(19) United States
(12) Patent Application Publication
(10) Pub. No.: US 2025/0194341 A1
(43) Pub. Date: Jun. 12, 2025

(54) DISPLAY APPARATUS HAVING A PIXEL DRIVING CIRCUIT

(71) Applicant: LG DISPLAY CO., LTD., Seoul (KR)

(72) Inventor: Sung Ju CHOI, Paju-si (KR)

(73) Assignee: LG DISPLAY CO., LTD., Seoul (KR)

(21) Appl. No.: 18/934,543

(22) Filed: Nov. 1, 2024

(30) Foreign Application Priority Data
Dec. 12, 2023 (KR) 10-2023-0179958

(51) Int. Cl. H10K 59/121; H10K 59/131

(52) U.S. Cl. CPC H10K 59/1213; H10K 59/131

(57) ABSTRACT

A display apparatus is disclosed to improve low gray-scale image display and increase driving current. A light-emitting device and a pixel driving circuit electrically connected to the light-emitting device may be disposed in each pixel area. The pixel driving circuit may include a driving thin film transistor. A semiconductor pattern of the driving thin film transistor may include a first active region and a second active region parallel to the first active region. A first sub-gate of the driving thin film transistor may be disposed on a first active channel of the first active region and a second active channel of the second active region. The driving thin film transistor may include a second sub-gate between the semiconductor pattern and the first sub-gate. The second active region may include a portion disposed outside the second sub-gate.

### CROSS-REFERENCE TO RELATED APPLICATIONS

This application claims the benefit of Korean Patent Application No. 10-2023-0179958, filed on Dec. 12, 2023, which is hereby incorporated by reference as if fully set forth herein.

### TECHNICAL FIELD

The present disclosure relates to a display apparatus in which a pixel driving circuit electrically connected to a light-emitting device is disposed in each pixel area.

### BACKGROUND

Generally, a display apparatus provides an image to a user. For example, the display apparatus may include a plurality of pixel areas. Each of the pixel areas may realize a specific color. For example, a light-emitting device may be disposed in each pixel area. The light-emitting device may emit light displaying a specific color. The light-emitting device may include a light-emitting layer between a first electrode and a second electrode.

A pixel driving circuit is electrically connected to the light-emitting device and may be disposed in each pixel area. An operation of the light-emitting device in each pixel area may be controlled by the pixel driving circuit in the corresponding pixel area. The pixel driving circuit of each pixel area may supply a driving current corresponding to a data signal to the light-emitting device of the corresponding pixel area according to a gate signal for one frame. The pixel driving circuit of each pixel area may include a driving thin film transistor and at least one switching thin film transistor.

The driving thin film transistor of each pixel area may generate the driving current corresponding to the data signal. For example, a gray-scale of color realized by each pixel area may be determined by the driving current generated by the driving thin film transistor of the corresponding pixel area. Thus, in the display apparatus, the driving thin film transistor of each pixel area may have different electrical characteristics from the switching thin film transistor of the corresponding pixel area. Therefore, in the display apparatus, a process of forming the pixel driving circuit in each pixel may be complicated. And, in the display apparatus, quality of the image may deteriorate due to different characteristics of the driving thin film transistor in each pixel area.

The description provided in the background section should not be assumed to be prior art merely because it is mentioned in or associated with the background section. The background section may include information that describes one or more aspects of the subject technology.

### SUMMARY

Accordingly, the present disclosure is directed to a display apparatus that substantially obviates one or more problems due to limitations and disadvantages of the related art.

An object of the present disclosure is to provide a display apparatus capable of simplifying a process of forming the pixel driving circuit in each pixel area.

Another object of the present disclosure is to provide a display apparatus capable of increasing both S-factor of the driving thin film transistor in each pixel area and a driving current generated by the driving thin film transistor.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a semiconductor pattern. The semiconductor pattern includes a first active region and a second active region. The second active region is disposed parallel to the first active region. A first sub-gate is disposed on the semiconductor pattern. The first sub-gate overlaps a first active channel of the first active region and a second active channel of the second active region. A second sub-gate is disposed between the semiconductor pattern and the first sub-gate. The second sub-gate is insulated from the semiconductor pattern. A first active drain of the first active region and a second active drain of the second active region are electrically connected to a drain electrode. A first active source of the first active region and a second active source of the second active region are electrically connected to a source electrode. A width of the second sub-gate on the second active channel is smaller than a width of the second sub-gate on the first active channel.

A width of the second sub-gate on the first active channel may be greater than a width of the first sub-gate on the first active channel.

The second sub-gate may be electrically connected to the first sub-gate. The first sub-gate may be disposed on a different layer from the second sub-gate.

The first sub-gate may be disposed on a different layer from the drain electrode and the source electrode.

The second active channel may include a first sub-channel and a second sub-channel. The first sub-channel may overlap the second sub-gate. The second sub-channel may be disposed outside the second sub-gate. A distance between the first sub-channel and the second sub-gate may be smaller than a distance between the second sub-channel and the first sub-gate.

A resistance of the second sub-channel may be a same as a resistance of the first sub-channel.

The second active channel may include a third sub-channel disposed outside the second sub-gate. A distance between the third sub-channel and the first sub-gate may be greater than a distance between the first sub-channel and the second sub-gate. The first sub-channel may be disposed between the second sub-channel and the third sub-channel.

The semiconductor pattern may be made of an oxide semiconductor. The amount of oxygen contained in the second active channel may be a same as the amount of oxygen contained in the first active channel.

In another aspect, there is provided a display apparatus comprising a device substrate. A first thin film transistor, a second thin film transistor and a light-emitting device are disposed on a pixel area of the device substrate. The first thin film transistor includes a first semiconductor pattern and a first gate electrode. The second thin film transistor includes a second semiconductor pattern and a second gate electrode. The light-emitting device is electrically connected to the second thin film transistor. The second gate electrode includes a first sub-gate and a second sub-gate. The first sub-gate overlaps a channel region of the second semiconductor pattern. The second sub-gate is disposed between the second semiconductor pattern and the first sub-gate. The channel region of the second semiconductor pattern includes a first active channel and a second active channel. The first active channel includes a portion overlapping with the second sub-gate. The second active channel is disposed outside the second sub-gate. A resistance of the second active channel is smaller than a resistance of the first active channel. The first active channel includes a first sub-channel and a second sub-channel. The first sub-channel overlaps the second sub-gate. The second sub-channel is disposed outside the second sub-gate.

A resistance of the second sub-channel may be a same as a resistance of the second active channel.

The second sub-gate may include a different material from the first sub-gate.

The first gate electrode may include a same material as the second sub-gate.

A first gate insulating layer may be disposed between the second semiconductor pattern and the second sub-gate. A second gate insulating layer may be disposed between the second sub-gate and the first sub-gate. The first gate electrode may be disposed between the first gate insulating layer and the second gate insulating layer.

An upper interlayer insulating layer may be disposed on the second gate insulating layer. The upper interlayer insulating layer may cover the first sub-gate. A storage capacitor may be disposed on the pixel area of the device substrate. The storage capacitor may include a first capacitor electrode, a second capacitor electrode and a third capacitor electrode. The first capacitor electrode may be disposed between the first gate insulating layer and the second gate insulating layer. The second capacitor electrode may be disposed between the second gate insulating layer and the upper interlayer insulating layer. The third capacitor electrode may be disposed on the upper interlayer insulating layer.

A channel region of the first semiconductor pattern may have a larger resistance than a drain region and a source region of the first semiconductor pattern. The first sub-channel may have a same resistance as the channel region of the first semiconductor pattern.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate aspect(s) of the present disclosure and together with the description serve to explain the principle of the present disclosure. In the drawings:

FIG. 1 is a view schematically showing a display apparatus according to an aspect of the present disclosure;

FIG. 2 is a view showing a circuit of a pixel area in the display apparatus according to the aspect of the present disclosure;

FIG. 3 is a view showing a cross-section taken along I-I′ of FIG. 1 and a cross-section of the pixel area in the display apparatus according to the aspect of the present disclosure;

FIG. 4 is a plan view showing a second thin film transistor of the pixel area in the display apparatus according to the aspect of the present disclosure;

FIG. 5 is a view showing cross-sections taken along II-II′ and III-III′ of FIG. 4;

FIG. 6 is a view showing cross-sections taken along IV-IV′ of FIG. 4;

FIG. 7 is an enlarged view of K1 region in FIG. 5;

FIG. 8 is an enlarged view of K2 region in FIG. 5;

FIG. 9 is a graph showing a driving current according to a voltage applied to a gate electrode according to a structure of a thin film transistor; and

FIGS. 10 to 22 are views showing the display apparatus according to another aspect of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided to allow the technical sprit of the present disclosure to be satisfactorily transferred to those skilled in the art, and thus the present disclosure may be embodied in other forms and is not limited to the embodiments described below. Any implementation described herein as an “example” is not necessarily to be construed as preferred or advantageous over other implementations.

The shapes, sizes, ratios, angles, numbers, and the like, which are illustrated in the drawings to describe various example embodiments of the present disclosure are merely given by way of example. Therefore, the present disclosure is not limited to the illustrations in the drawings. The same or similar elements are designated by the same reference numerals throughout the specification unless otherwise specified. In the following description where the detailed description of the relevant known function or configuration may unnecessarily obscure an important point of the present disclosure, a detailed description of such known function of configuration may be omitted.

In construing an element, the element is construed as including an error range or tolerance range although there is no explicit description of such an error or tolerance range.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element to come into contact with the second element, a third element may be interposed between the first element and the second element.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, embodiments of the present disclosure will be described in detail with reference to the accompanying drawings. Further, all the components of each display apparatus according to all embodiments of the present disclosure are operatively coupled and configured.

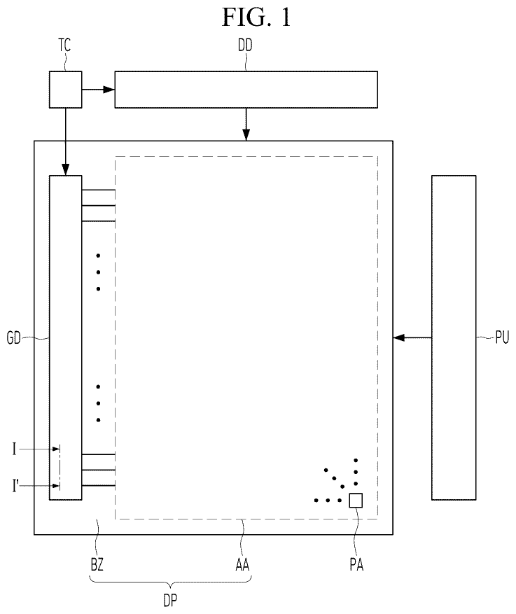

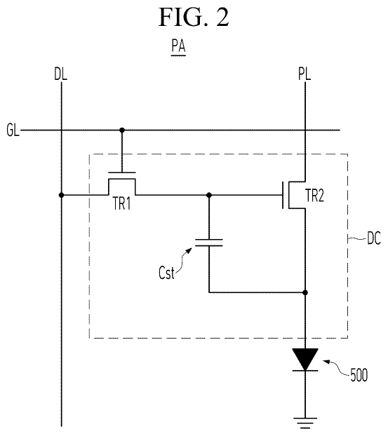

FIG. 1 is a view schematically showing a display apparatus according to an aspect of the present disclosure. FIG. 2 is a view showing a circuit of a pixel area in the display apparatus according to the aspect of the present disclosure.

Referring to FIGS. 1 and 2, the display apparatus according to the aspect of the present disclosure may include a display panel DP. The display panel DP may generate an image provided to a user. For example, the display panel DP may include a plurality of pixel areas PA. Various signals may be provided in each pixel area PA through signal wirings GL, DL and PL. For example, the signal wirings GL, DL and PL may include gate lines GL sequentially applying a gate signal to each pixel area PA, data lines DL applying a data signal to each pixel area PA, and power voltage supply lines PL supplying a power voltage to each pixel area PA. The gate lines GL may be electrically connected to a gate driver GD. The data lines DL may be electrically connected to a data driver DD. The power voltage supply lines PL may be electrically connected to a power unit PU.

The gate driver GD and the data driver DD may be controlled by a timing controller TC. For example, the gate driver GD may receive clock signals, reset signals and a start signal from the timing controller TC, and the data driver DD may receive digital video data and a source timing signal from the timing controller TC.

The display panel DP may include a display area AA including the pixel areas PA, and a bezel area BZ outside of the display area AA. The bezel area BZ may be disposed outside the pixel areas PA. For example, the bezel area BZ may surround the display area AA. Each of the signal wiring GL, DL and PL may be electrically connected to each pixel area PA across at least a portion of the bezel area BZ.

At least one of the gate driver GD, the data driver DD, the power unit PU and the timing controller TC may be disposed on the bezel area BZ of the display panel DP. For example, the display apparatus according to the aspect of the present disclosure may be a Gate In Panel (GIP) type display apparatus in which the gate driver GD is formed on the bezel area BZ of the display panel DP.

Each of the pixel areas PA may realize a specific color. For example, a light-emitting device 500 and a pixel driving circuit DC electrically connected to the light-emitting device 500 may be disposed in each pixel area PA. The pixel driving circuit DC of each pixel area PA may be electrically connected to the signal wirings GL, DL and PL. For example, the pixel driving circuit DC of each pixel area PA may be electrically connected to one of the gate lines GL, one of the data lines DL, and one of the power voltage supply lines PL. The pixel driving circuit DC of each pixel area PA may supply a driving current corresponding to the data signal to the light-emitting device 500 of the corresponding pixel area PA according to the gate signal for one frame. For example, the pixel driving circuit DC of each pixel area PA may include a first thin film transistor TR1, a second thin film transistor TR2 and a storage capacitor Cst, but is not limited thereto, and may include more or less elements than shown. For example, 3T1C, 4T1C, 5T1C, 3T2C, 4T2C, 5T2C, 6T2C, 7T1C, 7T2C, 8T2C structures, etc. are also possible. And more or less transistors and capacitors could be included in the pixel driving circuit DC.

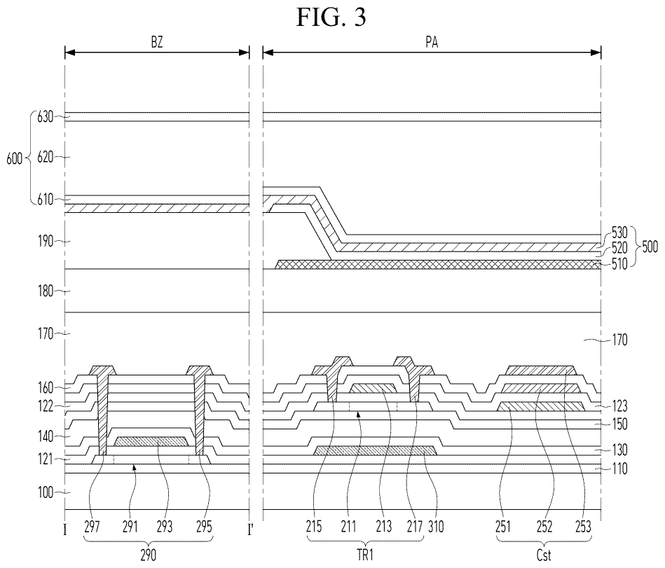

FIG. 3 is a view showing a cross-section taken along I-I′ of FIG. 1 and a cross-section of the pixel area in the display apparatus according to the aspect of the present disclosure.

Referring to FIGS. 2 and 3, the first thin film transistor TR1 of each pixel area PA may transmit the data signal to the second thin film transistor TR2 of the corresponding pixel area PA according to the gate signal. For example, the first thin film transistor TR1 of each pixel area PA may be a switching thin film transistor. The first thin film transistor TR1 of each pixel area PA may include a first semiconductor pattern 211, a first gate electrode 213, a first drain electrode 215 and a first source electrode 217. The first gate electrode 213 of each pixel area PA may be electrically connected to the corresponding gate line GL, and the first drain electrode 215 of each pixel area PA may be electrically connected to the corresponding date line DL.

The first semiconductor pattern 211 may include a semiconductor material. For example, the first semiconductor pattern 211 may include an oxide semiconductor, such as IGZO. In another example, the oxide semiconductors may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto. The first semiconductor pattern 211 may include a first drain region, a first channel region and a first source region. The first channel region may be disposed between the first drain region and the first source region. The first drain region and the first source region may have a smaller resistance than the first channel region. For example, the first drain region and the first source region may include a conductive region of an oxide semiconductor. The first channel region may be a region of an oxide semiconductor, which is not conductive.

The first gate electrode 213 may be disposed on a portion of the first semiconductor pattern 211. For example, the first gate electrode 213 may overlap the first channel region of the first semiconductor pattern 211. The first drain region and the first source region of the first semiconductor pattern 211 may be disposed outside the first gate electrode 213. The first gate electrode 213 may include a conductive material. For example, the first gate electrode 213 may include a metal, such as aluminum (Al), chrome (Cr), copper (Cu), molybdenum (Mo), titanium (Ti) and tungsten (W). The first gate electrode 213 may be separated from the first semiconductor pattern 211. The first gate electrode 213 may be insulated from the first semiconductor pattern 211. For example, the first drain region of the first semiconductor pattern 211 may be electrically connected to the first source region of the first semiconductor pattern 211 according to a voltage applied to the first gate electrode 213.

The first drain electrode 215 may include a conductive material. For example, the first drain electrode 215 may include a metal, such as aluminum (Al), chrome (Cr), copper (Cu), molybdenum (Mo), titanium (Ti) and tungsten (W). The first drain electrode 215 may include a different material from the first gate electrode 213. For example, the first drain electrode 215 may be disposed on a different layer from the first gate electrode 213. The first drain electrode 215 may be insulated from the first gate electrode 213. The first drain electrode 215 may be electrically connected to the first drain region of the first semiconductor pattern 211.

The first source electrode 217 may include a conductive material. For example, the first source electrode 217 may include a metal, such as aluminum (Al), chrome (Cr), copper (Cu), molybdenum (Mo), titanium (Ti) and tungsten (W). The first source electrode 217 may include a different material from the first gate electrode 213. For example, the first source electrode 217 may be disposed on a different layer from the first gate electrode 213. The first source electrode 217 may be insulated from the first gate electrode 213. The first source electrode 217 may be disposed on a same layer as the first drain electrode 215. The first source electrode 217 may include a same material as the first drain electrode 215. The first source electrode 217 may be formed by a same process as the first drain electrode 215. For example, the first source electrode 217 may be formed simultaneously with the first drain electrode 215. The first source electrode 217 may be separated from the first drain electrode 215. The first source electrode 217 may be electrically connected to the first source region of the first semiconductor pattern 211.

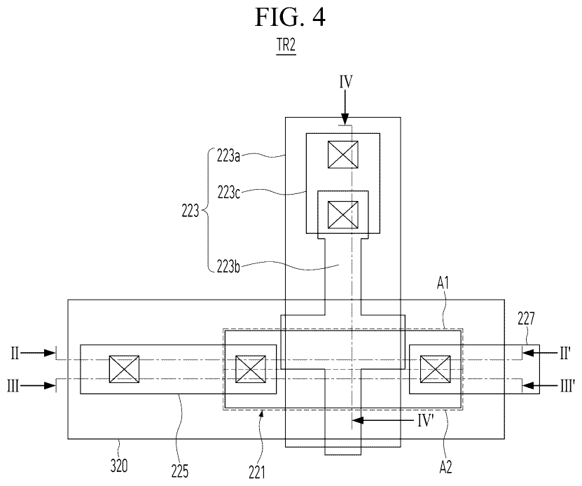

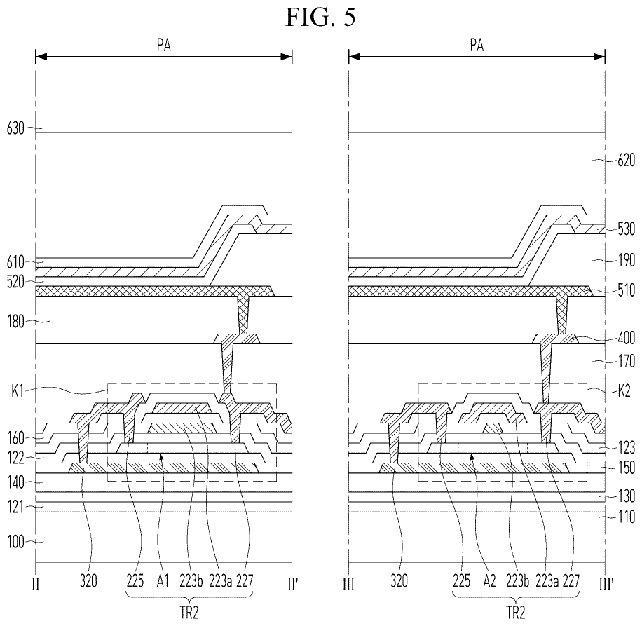

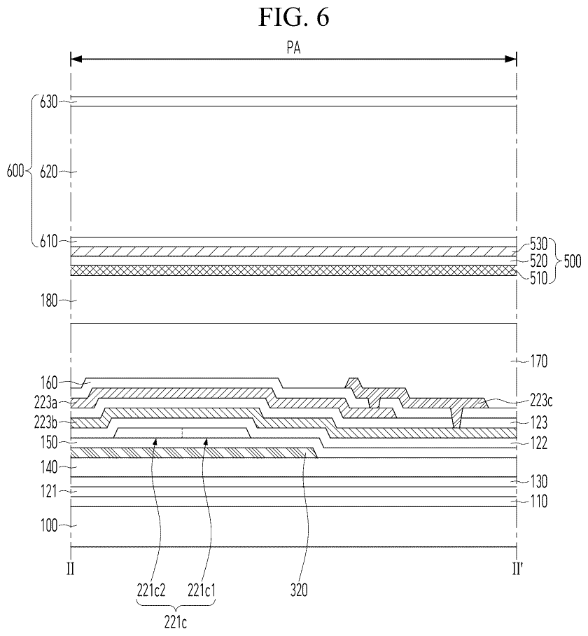

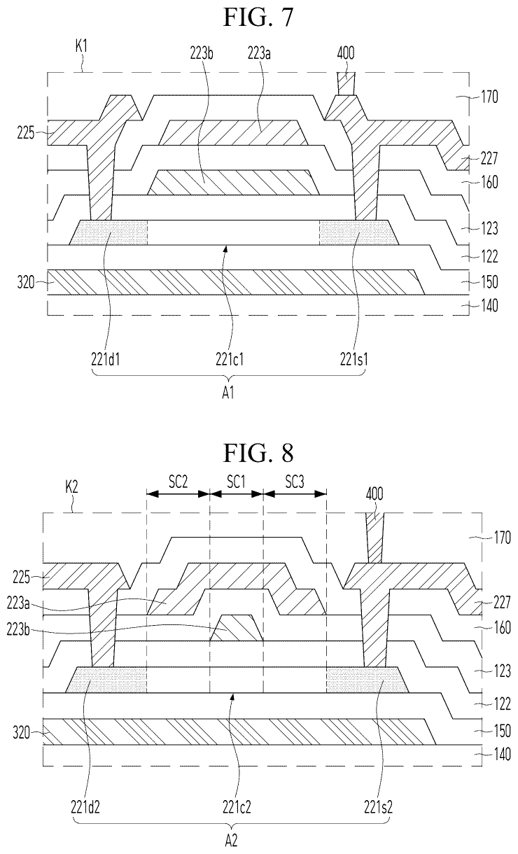

FIG. 4 is a plan view showing a second thin film transistor of the pixel area in the display apparatus according to the aspect of the present disclosure. FIG. 5 is a view showing cross-sections taken along II-II′ and III-III′ of FIG. 4. FIG. 6 is a view showing cross-sections taken along IV-IV′ of FIG. 4. FIG. 7 is an enlarged view of K1 region in FIG. 5. FIG. 8 is an enlarged view of K2 region in FIG. 5.

Referring to FIGS. 2 to 8, the second thin film transistor TR2 of each pixel area PA may generate the driving current corresponding to the data signal. For example, the second thin film transistor TR2 of each pixel area PA may be a driving thin film transistor. The second thin film transistor TR2 of each pixel area PA may include a second semiconductor pattern 221, a second gate electrode 223, a second drain electrode 225 and a second source electrode 227. For example, the second gate electrode 223 of each pixel area PA may be electrically connected to the first source electrode 217 of the corresponding pixel area PA, and the second drain electrode 225 of each pixel area PA may be electrically connected to the corresponding power voltage supply line PL.

The second semiconductor pattern 221 may include a first active region A1 and a second active region A2, as shown in FIGS. 4, 7 and 8. The second active region A2 may be disposed side by side with the first active region A1. The second active region A2 may extend parallel to the first active region A1. For example, a length of the second active region A2 may be a same as a length of the first active region A1. The second active region A2 may have a same width as the first active region A1. For example, a side surface of the second active region A2 may be in direct contact with a side surface of the first active region A1.

The first active region A1 may include a semiconductor material. For example, the first active region A1 may include an oxide semiconductor, such as IGZO. The first active region A1 may include a same material as the first semiconductor pattern 211. The first active region A1 may be disposed on a same layer as the first semiconductor pattern 211. The first active region A1 may be formed by a same process as the first semiconductor pattern 211. For example, the first active region A1 may be formed simultaneously with the first semiconductor pattern 211.

The first active region A1 may include a first active channel 221c1 between a first active drain 221d1 and a first active source 221s1. The first active drain 221d1 and the first active source 221s1 may have a smaller resistance than the first active channel 221c1. For example, the first active drain 221d1 and the first active source 221s1 may include a conductive region of an oxide semiconductor. The first active channel 221c1 may be a region of an oxide semiconductor, which is not conductive. For example, the first active channel 221c1 may have a same resistance as the first channel region.

The second active region A2 may include a semiconductor material. For example, the second active region A2 may include an oxide semiconductor, such as IGZO. The second active region A2 may include a same material as the first active region A1. The second active region A2 may be disposed on a same layer as the first active region A1. The second active region A2 may be formed by a same process as the first active region A1. For example, the second active region A2 may be formed simultaneously with the first active region A1. An interface between the first active region A1 and the second active region A2 may be not recognized.

The second active region A2 may include a second active channel 221c2 between a second active drain 221d2 and a second active source 221s2. The second active drain 221d2 and the second active source 221s2 may have a smaller resistance than the second active channel 221c2. For example, the second active drain 221d2 and the second active source 221s2 may include a conductive region of an oxide semiconductor. The second active channel 221c2 may be a region of an oxide semiconductor, which is not conductive.

The second active drain 221d2 may be in direct contact with the first active drain 221d1. The first active drain 221d1 and the second active drain 221d2 may constitute a second drain region of the second semiconductor pattern 221. For example, a length of the second active drain 221d2 may be a same as a length of the first active drain 221d1. A resistance of the second active drain 221d2 may be a same as a resistance of the first active drain 221d1. For example, the second active drain 221d2 may be formed simultaneously with the first active drain 221d1.

The second active source 221s2 may be in direct contact with the first active source 221s1. The first active source 221s1 and the second active source 221s2 may constitute a second source region of the second semiconductor pattern 221. For example, a length of the second active source 221s2 may be a same as a length of the first active source 221s1. The second active source 221s2 may have a same resistance as the first active source 221s1. For example, the second active source 221s2 may be formed simultaneously with the first active source 221s1.

The second active channel 221c2 may be in direct contact with the first active channel 221c1. The first active channel 221c1 and the second active channel 221c2 may constitute a second channel region 221c of the second semiconductor pattern 221. For example, a length of the second active channel 221c2 may be a same as a length of the first active channel 221c1. The second active channel 221c2 may have a same resistance as the first active channel 221c1. For example, the amount of oxygen included in the second active channel 221c2 may be a same as the amount of oxygen included in the first active channel 221c1.

The second gate electrode 223 may be disposed on a portion of the second semiconductor pattern 221. For example, the second gate electrode 223 may disposed on the second channel region 221c of the second semiconductor pattern 221. The second drain region and the second source region of the second semiconductor pattern 221 may be disposed outside the second gate electrode 223. The second gate electrode 223 may include a first sub-gate 223a and a second sub-gate 223b.

The first sub-gate 223a may be disposed on the second channel region 221c of the second semiconductor pattern 221. For example, the first active channel 221c1 and the second active channel 221c2 of the second semiconductor pattern 221 may overlap the first sub-gate 223a. The second drain region and the second source region of the second semiconductor pattern 221 may be disposed outside the first sub-gate 223a. The first sub-gate 223a may include a conductive material. For example, the first sub-gate 223a may include a metal, such as aluminum (Al), chrome (Cr), copper (Cu), molybdenum (Mo), titanium (Ti) and tungsten (W). The first sub-gate 223a may be insulated from the second semiconductor pattern 221.

The second sub-gate 223b may extend parallel to the first sub-gate 223a. The second sub-gate 223b may be disposed on a different layer from the first sub-gate 223a. For example, the second sub-gate 223b may be disposed between the second semiconductor pattern 221 and the first sub-gate 223a. The second sub-gate 223b may include a conductive material. For example, the second sub-gate 223b may include a metal, such as aluminum (Al), chrome (Cr), copper (Cu), molybdenum (Mo), titanium (Ti) and tungsten (W). The second sub-gate 223b may include a different material from the first sub-gate 223a. The second sub-gate 223b may be insulated from the second semiconductor pattern 221.

The second sub-gate 223b may overlap the first active channel 221c1 of the second semiconductor pattern 221. For example, the second sub-gate 223b may include a region disposed between the first active channel 221c1 of the second semiconductor pattern 221 and the first sub-gate 223a. A width of the second sub-gate 223b on the first active channel 221c1 may be greater than a width of the first sub-gate 223a on the first active channel 221c1. For example, the first active channel 221c1 of the second semiconductor pattern 221 may have an electrical conductivity corresponding to a voltage applied to the second sub-gate 223b. The first active drain 221d1 may be electrically connected to the first active source 221s1 when a voltage is applied to the second sub-gate 223b.

The second sub-gate 223b may include a region on the second active channel 221c2 of the second semiconductor pattern 221. A width of the second sub-gate 223b on the second active channel 221c2 may be smaller than a width of the second sub-gate 223b on the first active channel 221c1. A portion of the second active channel 221c2 may be disposed outside the second sub-gate 223b. For example, the second active channel 221c2 may include a first sub-channel SC1, a second sub-channel SC2 and a third sub-channel SC3, which are disposed side by side between the second active drain 221d2 and the second active source 221s2, the second sub-gate 223b may overlap the first sub-channel SC1 of the second active channel 221c2, and the second sub-channel SC2 and the third sub-channel SC3 of the second active channel 221c2 may be disposed outside the second sub-gate 223b. The first sub-channel SC1 of the second active channel 221c2 may have an electrical conductivity corresponding to a voltage applied to the second sub-gate 223b. The second sub-channel SC2 and the third sub-channel SC3 of the second active channel 221c2 may have an electrical conductivity based on a voltage applied to the first sub-gate 223a.

The first sub-channel SC1 may be disposed between the second sub-channel SC2 and the third sub-channel SC3. For example, the second sub-channel SC2 may be disposed between the second active drain 221d2 and the first sub-channel SC1, and the third sub-channel SC3 may be disposed between the first sub-channel SC1 and the second active source 221s2. A resistance of the second sub-channel SC2 and a resistance of the third sub-channel SC3 may be a same as a resistance of the first sub-channel SC1. A distance between the first sub-channel SC1 and the second sub-gate 223b may be smaller than a distance between the second sub-channel SC2 and the first sub-gate 223a and a distance between the third sub-channel SC3 and the first sub-gate 223a.

In a general thin film transistor, the voltage applied to the gate electrode to form a conductive channel in the channel region of the semiconductor pattern is defined as the threshold voltage. The threshold voltage of the thin film transistor is proportional to the distance between the semiconductor pattern and the gate electrode of the corresponding thin film transistor. That is, in the display apparatus according to the aspect of the present disclosure, a first threshold voltage applied to the second sub-gate 223b when a channel is formed in the first sub-channel SC1 may be lower than a second threshold voltage applied to the first sub-gate 223a when a channel is formed in the second sub-channel SC2 and the third sub-channel SC3. Thus, in the display apparatus according to the aspect of the present disclosure, a channel of the first sub-channel SC1 may be formed before a channel of the second sub-channel SC2 and a channel of the third sub-channel SC3. And, in the display apparatus according to the aspect of the present disclosure, when a channel of the second sub-channel SC2 and a channel of the third sub-channel SC3 are not formed, the second active drain 221d2 may not be electrically connected to the second active source 221s2. For example, if a voltage between the first threshold voltage and the second threshold voltage is applied to the first sub-gate 223a and the second sub-gate 223b, a channel of the first active channel 221c1 and a channel of the first sub-channel SC1 may be formed, but a channel of the second sub-channel SC2 and a channel of the third sub-channel SC3 may not be formed. Therefore, in the display apparatus according to the aspect of the present disclosure, when a voltage between the first threshold voltage and the second threshold voltage is applied to the first sub-gate 223a and the second sub-gate 223b, the first active drain 221d1 may be electrically connected to the first active source 221s1, and the second active drain 221d2 may not be electrically connected to the second active source 221s2.

In the display apparatus according to the aspect of the present disclosure, a voltage between the first threshold voltage and the second threshold voltage may be applied to the first sub-gate 223a and the second sub-gate 223b of each pixel area PA, when a low gray-scale image is realized. Thus, in the display apparatus according to the aspect of the present disclosure, when a low gray-scale image is to be output, only the first active region A1 of the second semiconductor pattern 221 in each pixel may be activated. That is, in the display apparatus according to the aspect of the present disclosure, when a low gray-scale image is to be output, the driving current applied to the light-emitting device 500 of each pixel area PA may be decreased. In addition, when a low gray-scale image is to be output, deviation of the driving current generated by the second thin film transistor TR2 of each pixel area PA may be reduced. Therefore, in the display apparatus according to the aspect of the present disclosure, the quality of a low gray-scale image may be improved.

In the display apparatus according to the aspect of the present disclosure, when a voltage higher than the second threshold voltage is applied to the first sub-gate 223a and the second sub-gate 223b of each pixel area PA, a channel of the second sub-channel SC2 and a channel of the third sub-channel SC3 may be formed, and the second active drain 221d2 may be electrically connected to the second active source 221s2. For example, in the display apparatus according to the aspect of the present disclosure, when a voltage higher than the second threshold voltage is applied to the first sub-gate 223a and the second sub-gate 223b of each pixel area PA to output a high gray-scale image, both of the first active channel 221c1 and the second active channel 221c2 in each pixel area PA may be activated. That is, in the display apparatus according to the aspect of the present disclosure, when a high gray-scale image it to be output, the driving current generated by the second thin film transistor TR2 of each pixel area PA may be increased. Therefore, in the display apparatus according to the aspect of the present disclosure, both of the quality of a low gray-scale image and the quality of a high gray-scale image may be improved.

And, in the display apparatus according to the aspect of the present disclosure, a channel of the second sub-channel SC2 and a channel of the third sub-channel SC3 in each pixel area PA may function as an effective channel of the second active channel 221c2. Generally, a driving current generated by a thin film transistor may be inversely proportional to a channel length of the corresponding thin film transistor. Thus, in the display apparatus according to the aspect of the present disclosure, the driving current generated in the second active channel 221c2 of each pixel area PA may be larger than the driving current generated in the first active channel 221c1 of the corresponding pixel area PA. Therefore, in the display apparatus according to the aspect of the present disclosure, efficiency of the second thin film transistor TR2 in each pixel area PA may be improved.

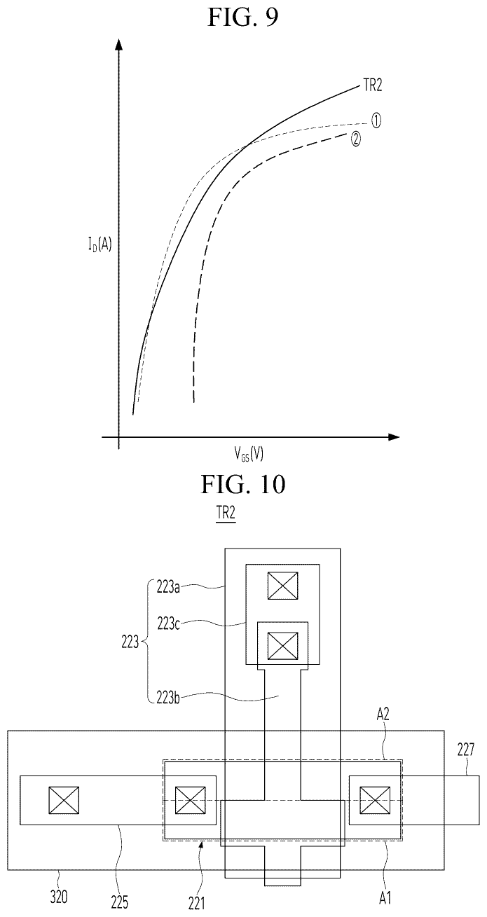

FIG. 9 is a graph showing a driving current according to a voltage applied to a gate electrode in a first comparative example thin film transistor \textcircled{1} including only a channel region in which a channel is formed by a first threshold voltage, a second comparative example thin film transistor \textcircled{2} including only a channel region in which a channel is formed by a second threshold voltage, and a second thin film transistor TR2 according to the aspect of the present disclosure. Here, the channel region of the first comparative example thin film transistor \textcircled{1}, the channel region of the second comparative example thin film transistor \textcircled{2}, and the second channel region 221c of the second thin film transistor TR2 according to the aspect of the present disclosure may be formed to have a same length and a same width.

Referring to FIG. 9, a threshold voltage of the second thin film transistor TR2 according to the aspect of the present disclosure may be lower than a threshold voltage of the first comparative example thin film transistor \textcircled{1} and a threshold voltage of the second comparative example thin film transistor \textcircled{2}. In addition, the driving current generated by the second thin film transistor TR2 according to the aspect of the present disclosure in a high voltage may be larger than the driving current generated by the first comparative example thin film transistor \textcircled{1} and the driving current generated by the second comparative example thin film transistor \textcircled{2} in a high voltage. Further, in a section to which a relatively low voltage is applied, the second thin film transistor TR2 according to the aspect of the present disclosure may increase the driving current according to the increase in voltage smaller than the first comparative example thin film transistor \textcircled{1} and the second comparative example thin film transistor \textcircled{2}. In the display apparatus according to the aspect of the present disclosure, the driving current applied to the light-emitting device 500 of each pixel area PA may be effectively controlled according to a gray-scale of a realized image without deteriorating the characteristics of the second thin film transistor TR2 in the corresponding pixel area PA. Therefore, in the display apparatus according to the aspect of the present disclosure, power consumption may be reduced based on improved driving of the display with low power.

Referring to FIGS. 2 to 8, the second sub-gate 223b may include a same material as the first gate electrode 213. The second sub-gate 223b may be disposed on a same layer as the first gate electrode 213. The second sub-gate 223b may be formed by a same process as the first gate electrode 213. For example, the second sub-gate 223b may be formed simultaneously with the first gate electrode 213. In some examples, the first sub-gate 223a may include a different material from the first gate electrode 213. The first sub-gate 223a may be disposed on a different layer from the first gate electrode 213.

The second sub-gate 223b may be electrically connected to the first sub-gate 223a. For example, the second gate electrode 223 may include a connection gate 223c electrically connecting the first sub-gate 223a to the second sub-gate 223b. The electrical connection between the first sub-gate 223a and the second sub-gate 223b may be formed outside the second semiconductor pattern 221. For example, the connection gate 223c may be disposed outside the second semiconductor pattern 221. The second semiconductor pattern 221 may not overlap the connection gate 223c. Thus, in the display apparatus according to the aspect of the present disclosure, a channel of the second channel region 221c may not be formed by the connection gate 223c. Therefore, in the display apparatus according to the aspect of the present disclosure, based on the connection gate 223c of the corresponding pixel area PA, this configuration may prevent or reduce deviation in the characteristics of the second thin film transistor TR2 in each pixel area PA.

The connection gate 223c may be disposed on a different layer from the first sub-gate 223a and the second sub-gate 223b. The connection gate 223c may include a different material from the first sub-gate 223a and the second sub-gate 223b. For example, the connection gate 223c may be disposed on a same layer as the first drain electrode 215 and the first source electrode 217. The connection gate 223c may include a same material as the first drain electrode 215 and the first source electrode 217. The connection gate 223c may be formed by a same process as the first drain electrode 215 and the first source electrode 217. For example, the connection gate 223c may be formed simultaneously with the first drain electrode 215 and the first source electrode 217. Thus, in the display apparatus according to the aspect of the present disclosure, change process efficiency is minimized or reduced due to a process of forming the second gate electrode 223.

The second drain electrode 225 may include a conductive material. For example, the second drain electrode 225 may include a metal, such as aluminum (Al), chrome (Cr), copper (Cu), molybdenum (Mo), titanium (Ti) and tungsten (W). The second drain electrode 225 may include a different material from the first sub-gate 223a and the second sub-gate 223b. The second drain electrode 225 may be disposed on a different layer from the first sub-gate 223a and the second sub-gate 223b. For example, the second drain electrode 225 may be disposed on a same layer as the connection gate 223c. The second drain electrode 225 may include a same material as the connection gate 223c. The second drain electrode 225 may be formed by a same process as the connection gate 223c. For example, the second drain electrode 225 may be formed simultaneously with the connection gate 223c. The second drain electrode 225 may be separated from the connection gate 223c. The second drain electrode 225 may be insulated from the second gate electrode 223. The second drain electrode 225 may be electrically connected to the first active drain 221d1 and the second active drain 221d2 of the second semiconductor pattern 221.

The second source electrode 227 may include a conductive material. For example, the second source electrode 227 may include a metal, such as aluminum (Al), chrome (Cr), copper (Cu), molybdenum (Mo), titanium (Ti) and tungsten (W). The second source electrode 227 may include a different material from the first sub-gate 223a and the second sub-gate 223b. The second source electrode 227 may be disposed on a different layer from the first sub-gate 223a and the second sub-gate 223b. For example, the second source electrode 227 may be disposed on a same layer as the second drain electrode 225. The second source electrode 227 may include a same material as the second drain electrode 225. The second source electrode 227 may be formed by a same process as the second drain electrode 225. For example, the second source electrode 227 may be formed simultaneously with the second drain electrode 225. The second source electrode 227 may be separated from the connection gate 223c and the second drain electrode 225. The second source electrode 227 may be insulated from the second gate electrode 223. The second source electrode 227 may be electrically connected to the first active source 221s1 and the second active source 221s2 of the second semiconductor pattern 221.

The storage capacitor Cst of each pixel area PA may maintain a signal applied to the second gate electrode 223 of the corresponding pixel area PA for one frame. For example, the storage capacitor Cst of each pixel area PA may be electrically connected between the second gate electrode 223 and the second source electrode 227 of the corresponding pixel area PA. The storage capacitor Cst of each pixel area PA may have a stacked structure of capacitor electrodes 251, 252 and 253. The storage capacitor Cst of each pixel area PA may be formed by using a process of forming the first thin film transistor TR1 and the second thin film transistor TR2 of the corresponding pixel area PA. For example, the storage capacitor Cst of each pixel area PA may include a first capacitor electrode 251 disposed on a same layer as the second sub-gate 223b, a capacitor electrode 252 disposed on a same layer as the first sub-gate 223a, and a third capacitor electrode 253 disposed on a same layer as the second source electrode 227. Thus, in the display apparatus according to the aspect of the present disclosure, a size occupied by the storage capacitor Cst in each pixel area PA may be minimized or reduced, without decreasing process efficiency.

The gate driver GD formed in the bezel area BZ may include at least one circuit thin film transistor 290. The circuit thin film transistor 290 may be a switching thin film transistor. For example, the circuit thin film transistor 290 may include a circuit semiconductor pattern 291, a circuit gate electrode 293, a circuit drain electrode 295 and a circuit source electrode 297.

The circuit semiconductor pattern 291 may include a semiconductor material. The circuit semiconductor pattern 291 may include a material different from the first semiconductor pattern 211, the first active region A1 and the second active region A2 of each pixel area PA. For example, the circuit semiconductor pattern 291 may include low-temperature poly-Si (LTPS). The circuit semiconductor pattern 291 may be disposed on a different layer from the first semiconductor pattern 211, the first active region A1 and the second active region A2 of each pixel area PA. However, the present disclosure is not limited thereto, and the circuit semiconductor pattern 291 may include a same material as that of the first semiconductor pattern 211 or the second semiconductor pattern 221, and/or disposed on a same layer as the first semiconductor pattern 211 or the second semiconductor pattern 221.

The circuit semiconductor pattern 291 may include a circuit drain region, a circuit channel region, and a circuit source region. The circuit channel region may be disposed between the circuit drain region and the circuit source region. The circuit drain region and the circuit source region may have a lower resistance than the circuit channel region. For example, the circuit drain region and the circuit source region may include conductive impurities. The circuit channel region may be a region, which is not doped with conductive impurities.

The circuit gate electrode 293 may be disposed on a portion of the circuit semiconductor pattern 291. For example, the circuit gate electrode 293 may overlap the circuit channel region of the circuit semiconductor pattern 291. The circuit drain region and the circuit source region of the circuit semiconductor pattern 291 may be disposed outside the circuit gate electrode 293. The circuit gate electrode 293 may include a conductive material. For example, the circuit gate electrode 293 may include a metal, such as aluminum (Al), chrome (Cr), copper (Cu), molybdenum (Mo), titanium (Ti) and tungsten (W). The circuit gate electrode 293 may be insulated from the circuit semiconductor pattern 291. The circuit drain region of the circuit semiconductor pattern 291 may be electrically connected to the circuit source region of the circuit semiconductor pattern 291 according to a voltage applied to the circuit gate electrode 293.

The circuit gate electrode 293 may include on a different material from the first gate electrode 213, the first sub-gate 223a and the second sub-gate 223b of each pixel area PA. The circuit gate electrode 293 may be disposed on a different layer from the first gate electrode 213, the first sub-gate 223a and the second sub-gate 223b of each pixel area PA.

The circuit drain electrode 295 may include a conductive material. For example, the circuit drain electrode 295 may include a metal, such as aluminum (Al), chrome (Cr), copper (Cu), molybdenum (Mo), titanium (Ti) and tungsten (W). The circuit drain electrode 295 may include a different material from the circuit gate electrode 293. For example, the circuit drain electrode 295 may be disposed on a different layer from the circuit gate electrode 293. The circuit drain electrode 295 may be insulated from the circuit gate electrode 293. For example, the circuit drain electrode 295 may be disposed on a same layer as the first drain electrode 215 of each pixel area PA. The circuit drain electrode 295 may include a same material as the first drain electrode 215 of each pixel area PA. The circuit drain electrode 295 may be formed by a same process as the first drain electrode 215 of each pixel area PA. For example, the circuit drain electrode 295 may be formed simultaneously with the first drain electrode 215 of each pixel area PA. The circuit drain electrode 295 may be electrically connected to the circuit drain region of the circuit semiconductor pattern 291.

The circuit source electrode 297 may include a conductive material. For example, the circuit source electrode 297 may include a metal such as aluminum (Al), chrome (Cr), copper (Cu), molybdenum (Mo), titanium (Ti) and tungsten (W). The circuit source electrode 297 may include a different material from the circuit gate electrode 293. For example, the circuit source electrode 297 may be disposed on a different layer from the circuit gate electrode 293. The circuit source electrode 297 may be insulated from the circuit gate electrode 293. For example, the circuit source electrode 297 may be disposed on a same layer as the circuit drain electrode 295. The circuit source electrode 297 may include a same material as the circuit drain electrode 295. The circuit source electrode 297 may be formed by a same process as the circuit drain electrode 295. For example, the circuit source electrode 297 may be formed simultaneously with the circuit drain electrode 295. The circuit source electrode 297 may be separated from the circuit drain electrode 295. The circuit source electrode 297 may be electrically connected to the circuit source region of the circuit semiconductor pattern 291.

The pixel driving circuit DC of each pixel area PA and the circuit thin film transistor 290 may be supported by a device substrate 100. For example, the first thin film transistor TR1, the second thin film transistor TR2 and the storage capacitor Cst of the pixel driving circuit DC in each pixel area PA may be disposed on the corresponding pixel area PA of the device substrate 100. The circuit thin film transistor 290 may be disposed on the bezel area BZ of the device substrate 100. The device substrate 100 may include an insulating material. For example, the device substrate 100 may include glass or plastic. In another example, the device substrate 100 may include a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

A plurality of insulating layers prevent unnecessary electrical connection and may be disposed on the device substrate 100. For example, a lower buffer layer 110, a lower gate insulating layer 121, a first upper gate insulating layer 122, a second upper gate insulating layer 123, a lower interlayer insulating layer 130, a separation insulating layer 140, an upper buffer layer 150, an upper interlayer insulating layer 160, a lower planarization layer 170, an upper planarization layer 180 and a bank insulating layer 190 may be disposed on the device substrate 100. It is to be noted that, although FIGS. 2 to 8 shows an example of the layer structure of the display apparatus according to the present disclosure, but embodiments of the present disclosure are not limited thereto. For example, one or more of the plurality of insulating layers 110, 121, 122, 123, 130, 140, 150, 160, 170, 180 and 190 may be omitted, changed, or replaced with other layers. Thus, the structure shown in FIGS. 2 to 8 is provided by way of example only, and the present disclosure is not limited thereto.

The lower buffer layer 110 may be disposed close to the device substrate 100. The lower buffer layer 110 may prevent or reduce pollution due to the device substrate 100 in a process of forming the pixel driving circuit DC of each pixel area PA and the circuit thin film transistor 290. For example, an upper surface of the device substrate 100 toward the pixel driving circuit DC of each pixel area PA and the circuit thin film transistor 290 may be completely covered by the lower buffer layer 110. The lower buffer layer 110 may be in direct contact with the upper surface of the device substrate 100. The pixel driving circuit DC of each pixel area PA and the circuit thin film transistor 290 may be disposed on the lower buffer layer 110. The lower buffer layer 110 may include an insulating material. For example, the lower buffer layer 110 may include an inorganic insulating material, such as silicon oxide (SiOx) and silicon nitride (SiNx). The lower buffer layer 110 may have a multi-layer structure. For example, the lower buffer layer 110 may have a stacked structure of an inorganic insulating layer made of silicon oxide (SiOx) and an inorganic insulating layer made of silicon nitride (SiNx).

The lower gate insulating layer 121 may be disposed on the lower buffer layer 110. The circuit gate electrode 293 may be insulated from the circuit semiconductor pattern 291 by the lower gate insulating layer 121. For example, the circuit semiconductor pattern 291 may be disposed between the lower buffer layer 110 and the lower gate insulating layer 121. The lower gate insulating layer 121 may cover the circuit semiconductor pattern 291. The circuit gate electrode 293 may be disposed on the lower gate insulating layer 121. The lower gate insulating layer 121 may include an insulating material. For example, the lower gate insulating layer 121 may include an inorganic insulating material, such as silicon oxide (SiOx) and silicon nitride (SiNx).

The lower interlayer insulating layer 130 may be disposed on the lower gate insulating layer 121. The circuit drain electrode 295 and the circuit source electrode 297 may be insulated from the circuit gate electrode 293 by the lower interlayer insulating layer 130. For example, the circuit gate pattern 293 may be disposed between the lower gate insulating layer 121 and the lower interlayer insulating layer 130. The lower interlayer insulating layer 130 may cover the circuit gate electrode 293. The circuit drain electrode 295 and the circuit source electrode 297 may be disposed on the lower interlayer insulating layer 130. The lower interlayer insulating layer 130 may include an insulating material. For example, the lower interlayer insulating layer 130 may include an inorganic insulating material, such as silicon oxide (SiOx) and silicon nitride (SiNx).

A first light-blocking pattern 310 may be disposed between the lower gate insulating layer 121 and the lower interlayer insulating layer 130 of each pixel area PA. The first light-blocking pattern 310 of each pixel area PA may include a material absorbing or reflecting light. For example, the first light-blocking pattern 310 of each pixel area PA may include a metal. The first light-blocking pattern 310 of each pixel area PA may include a same material as the circuit gate electrode 293. The first light-blocking pattern 310 of each pixel area PA may be disposed on a same layer as the circuit gate electrode 293. The first light-blocking pattern 310 of each pixel area PA may be formed by a same process as the circuit gate electrode 293. For example, the first light-blocking pattern 310 of each pixel area PA may be formed simultaneously with the circuit gate electrode 293.

The first light-blocking pattern 310 of each pixel area PA may overlap the first semiconductor pattern 211 of the corresponding pixel area PA. For example, light traveling toward the first semiconductor pattern 211 of each pixel area PA by passing through the device substrate 100 may be blocked by the first light-blocking pattern 310 of the corresponding pixel area PA. Thus, in the display apparatus according to the aspect of the present disclosure, change in characteristics of the first thin film transistor TR1 in each pixel area PA due to external light introduced through the device substrate 100 may be prevented or reduced.

A specific voltage may be applied to the first light-blocking pattern 310 of each pixel area PA. For example, the first light-blocking pattern 310 of each pixel area PA may be electrically connected to the first gate electrode 213 of the corresponding pixel area PA. Thus, in the display apparatus according to the aspect of the present disclosure, the first light-blocking pattern 310 of each pixel area PA may function as a gate electrode of the first thin film transistor TR1 in the corresponding pixel area PA. The first semiconductor pattern 211 of each pixel area PA may be disposed between the first light-blocking pattern 310 and the first gate electrode 213 of the corresponding pixel area PA. That is, in the display apparatus according to the aspect of the present disclosure, a channel of the first semiconductor pattern 211 may be formed by a voltage applied to the first gate electrode 213 of the corresponding pixel area PA and a voltage applied to the first light-blocking pattern 310 of the corresponding pixel area PA. Therefore, in the display apparatus according to the aspect of the present disclosure, response speed of the first thin film transistor TR1 in each pixel area PA may be increased.

The separation insulating layer 140 may be disposed on the lower interlayer insulating layer 130. The separation insulating layer 140 may prevent or reduce the deterioration and the damage of the circuit semiconductor pattern 291 due to a process of forming the pixel driving circuit DC in each pixel area PA. For example, the first thin film transistor TR1, the second thin film transistor TR2 and the storage capacitor Cst of each pixel area PA may be disposed on the separation insulating layer 140. The separation insulating layer 140 may include an insulating material. For example, the separation insulating layer 140 may be an inorganic insulating material, such as silicon oxide (SiOx) and silicon nitride (SiNx). The separation insulating layer 140 may have a multi-layer structure. For example, the separation insulating layer 140 may have a stacked structure of an inorganic insulating layer made of silicon oxide (SiOx) and an inorganic insulating layer made of silicon nitride (SiNx). A thickness of the separation insulating layer 140 may be a larger than a thickness of the lower interlayer insulating layer 130. Thus, in the display apparatus according to the aspect of the present disclosure, damage of the circuit semiconductor pattern 291 due to a process of forming the pixel driving circuit DC of each pixel area PA may be effectively prevented or reduced.

The upper buffer layer 150 may be disposed on the separation insulating layer 140. The upper buffer layer 150 may include an insulating material. For example, the upper buffer layer 150 may include an inorganic insulating material, such as silicon oxide (SiOx) and silicon nitride (SiNx). A second light-blocking pattern 320 may be disposed between the separation insulating layer 140 and the upper buffer layer 150 of each pixel area PA. For example, the upper buffer layer 150 may prevent or reduce pollution due to the second light-blocking pattern 320 of each pixel area PA in a process of forming the first semiconductor pattern 211 and the second semiconductor pattern 221 of each pixel area PA. For example, the pixel driving circuit DC of each pixel area PA may be disposed on the upper buffer layer 150.

The second light-blocking pattern 320 of each pixel area PA may include a material absorbing or reflecting light. For example, the second light-blocking pattern 320 of each pixel area PA may include a metal. The second light-blocking pattern 320 of each pixel area PA may overlap the second semiconductor pattern 221 of the corresponding pixel area PA. For example, light traveling toward the second semiconductor pattern 221 of each pixel area PA by passing through the device substrate 100 may be blocked by the second light-blocking pattern 320 of the corresponding pixel area PA. Thus, in the display apparatus according to the aspect of the present disclosure, the second light-blocking pattern 320 may prevent or reduce change in characteristics of the second thin film transistor TR2 in each pixel area PA due to the external light introduced through the device substrate 100. That is, in the display apparatus according to the aspect of the present disclosure, deviation in characteristics of the second thin film transistor TR2 due to the external light may be prevented or reduced. Therefore, in the display apparatus according to the aspect of the present disclosure, deterioration in quality of the image due to the external light may be prevented or reduced.

A specific voltage may be applied to the second light-blocking pattern 320 of each pixel area PA. For example, the second light-blocking pattern 320 of each pixel area PA may be electrically connected to the second drain electrode 225 of the corresponding pixel area PA. Thus, in the display apparatus according to the aspect of the present disclosure, change in characteristics of the second thin film transistor TR2 in each pixel area PA due to the external light may be effectively prevented or reduced.

A distance between the second light-blocking pattern 320 and the second semiconductor pattern 221 in each pixel area PA may be smaller than a distance between the first light-blocking pattern 310 and the first semiconductor pattern 211 in the corresponding pixel area PA. Generally, the amount of change in the effective gate voltage of a thin film transistor disposed on a conductive pattern may be determined by the following equation. Here, ΔV_{eff} represents the amount of change in the effective gate voltage, ΔV_{GAT} represents the amount of change in a voltage applied to the gate electrode, C1 represents capacitance of the parasitic capacitor formed between the conductive pattern and a semiconductor pattern of the corresponding thin film transistor, C2 represents capacitance of the parasitic capacitor formed between the semiconductor pattern and the gate electrode of the corresponding thin film transistor, and C_{ACT} represents capacitance of the parasitic capacitor formed by a voltage applied to a drain region and a source region of the corresponding thin film transistor.

$$Δ {V}_{eff} = \frac{C 2}{C 2 + {C}_{ACT} + C 1} \times Δ {V}_{GAT} \qquad ( Equation 1 )$$

Capacitance of a capacitor is inversely proportional to a distance between conductors constituting the corresponding capacitor. In the display apparatus according to the aspect of the present disclosure, the capacitance of the parasitic capacitor formed between the second light-blocking pattern 320 and the second semiconductor pattern 221 of each pixel area PA may be larger than the capacitance of the parasitic capacitor formed between the first light-blocking pattern 310 and the first semiconductor pattern 211 of the corresponding pixel area PA. Thus, in the display apparatus according to the aspect of the present disclosure, the amount of change in the effective gate voltage of the second thin film transistor TR2 in each pixel area PA may be smaller than the amount of change in the effective gate voltage of the first thin film transistor TR1 in the corresponding pixel area PA. In a general thin film transistor, when the amount of change in the effective gate voltage is reduced, the current may decrease according to change in a voltage applied to the gate electrode of the corresponding thin film transistor, and an S-factor of the corresponding thin film transistor may be increased. Here, the S-factor of the thin film transistor is an inverse ratio of the amount of change in the current generated by the corresponding thin film transistor and the amount of change in the voltage applied to the gate electrode of the corresponding thin film transistor. That is, in the display apparatus according to the aspect of the present disclosure, the S-factor of the second thin film transistor TR2 in each pixel area PA, and the amount of change in the driving current generated by the second thin film transistor TR2 of each pixel area PA according to change in the voltage applied to the second gate electrode 223 of the corresponding pixel area PA may be reduced. Therefore, in the display apparatus according to the aspect of the present disclosure, the display apparatus may prevent or reduce occurrence of stains due to deviation of luminance and improve the quality of the image.

The first upper gate insulating layer 122 may be disposed on the upper buffer layer 150. The first gate electrode 213 of each pixel area PA may be insulated from the first semiconductor pattern 211 of the corresponding pixel area PA by the first upper gate insulating layer 122. The second sub-gate 223b of each pixel area PA may be insulated from the first active region A1 and the second active region A2 of the corresponding pixel area PA by the first upper gate insulating layer 122. For example, the first upper gate insulating layer 122 may cover the first semiconductor pattern 211 and the second semiconductor pattern 221 of each pixel area PA. The first gate electrode 213 and the second sub-gate 223b of each pixel area PA may be disposed on the first upper gate insulating layer 122. The first upper gate insulating layer 122 may include an insulating material. For example, the first upper gate insulating layer 122 may be an inorganic insulating material, such as silicon oxide (SiOx) and silicon nitride (SiNx).

The second upper gate insulating layer 123 may be disposed on the first upper gate insulating layer 122. The first sub-gate 223a of each pixel area PA may be separated from the second sub-gate 223b of the corresponding pixel area PA by the second upper gate insulating layer 123. For example, the second upper gate insulating layer 123 may cover the first gate electrode 213 and the second sub-gate 223b of each pixel area PA. The first sub-gate 223a of each pixel area PA may be disposed on the second upper gate insulating layer 123. The second upper gate insulating layer 123 may include an insulating material. For example, the second upper gate insulating layer 123 may include an inorganic insulating material, such as silicon oxide (SiOx) and silicon nitride (SiNx). The second upper gate insulating layer 123 may include a same material as the first upper gate insulating layer 122. For example, an interface between the first upper gate insulating layer 122 and the second upper gate insulating layer 123 may not be recognized.

In each pixel area PA, only the first upper gate insulating layer 122 may be disposed between the first active channel 221c1 and the second sub-gate 223b and between the first sub-channel SC1 and the second sub-gate 223b of the second active channel 221c2. In each pixel area PA, the first upper gate insulating layer 122 and the second upper gate insulating layer 123 may be disposed between the second sub-channel SC2 of the second active channel 221c2 and the first sub-gate 223a, and between the third sub-channel SC3 of the second active channel 221c2 and the first sub-gate 223a. For example, a distance between the first sub-channel SC1 and second sub-gate 223b in each pixel area PA may be equal to a distance between the first active channel 221c1 and the second sub-gate 223b in the corresponding pixel area PA, and a distance between the second sub-channel SC2 and the first sub-gate 223a and a distance between the third sub-channel SC3 and the first sub-gate 223a in each pixel area PA may be larger than a distance between the first sub-channel SC1 and the second sub-gate 223b in the corresponding pixel area PA. That is, in the display apparatus according to the aspect of the present disclosure, capacitance of the parasitic capacitor formed between the second sub-channel SC2 and the first sub-gate 223a and capacitance of the parasitic capacitor formed between the third sub-channel SC3 and the first sub-gate 223a in each pixel area PA may be smaller than capacitance of the parasitic capacitor formed between the first active channel 221c1 and the second sub-gate 223b in the corresponding pixel area PA. Thus, in the display apparatus according to the aspect of the present disclosure, the S-factor of the second thin film transistor TR2 in each pixel area PA may be increased based on the distance between the second sub-channel SC2 and the first sub-gate 223a and the distance between the third sub-channel SC3 and the first sub-gate 223a in the corresponding pixel area PA. That is, in the display apparatus according to the aspect of the present disclosure, the current change flowing through the second active region A2 of each pixel area PA may not be large based on a voltage change applied to the first sub-gate 223a of the corresponding pixel area PA. Therefore, in the display apparatus according to the aspect of the present disclosure, deviation in characteristics of the second thin film transistors TR2 may be effectively prevented or reduced.

The upper interlayer insulating layer 160 may be disposed on the second upper gate insulating layer 123. The upper interlayer insulating layer 160 may cover the first sub-gate 223a of each pixel area PA. The upper interlayer insulating layer 160 may include an insulating material. For example, the upper interlayer insulating layer 160 may include an inorganic insulating material, such as silicon oxide (SiOx) and silicon nitride (SiNx).

The first drain electrode 215, the first source electrode 217, the second drain electrode 225, the second source electrode 227 and the connection gate 223c of each pixel area PA may be disposed on the upper interlayer insulating layer 160. For example, the first drain electrode 215 and the first source electrode 217 of each pixel area PA may be insulated from the first gate electrode 213 of the corresponding pixel area PA by the first upper gate insulating layer 122, the second upper gate insulating layer 123 and the upper interlayer insulating layer 160. The connection gate 223c of each pixel area PA may be separated from the first sub-gate 223a of the corresponding pixel area PA by the upper interlayer insulating layer 160. For example, the first sub-gate 223a of each pixel area PA may be insulated from the second drain electrode 225 and the second source electrode 227 of the corresponding pixel area PA by the upper interlayer insulating layer 160.

The first drain electrode 215 of each pixel area PA may be electrically connected to the first drain region of the first semiconductor pattern 211 in the corresponding pixel area PA passing through the first upper gate insulating layer 122, the second upper gate insulating layer 123 and the upper interlayer insulating layer 160. The first source electrode 217 of each pixel area PA may be electrically connected to the first source region of the first semiconductor pattern 211 in the corresponding pixel area PA passing through the first upper gate insulating layer 122, the second upper gate insulating layer 123 and the upper interlayer insulating layer 160. The second drain electrode 225 of each pixel area PA may be electrically connected to the first active drain 221d1 and the second active drain 221d2 of the second semiconductor pattern 221 in the corresponding pixel area PA passing through the first upper gate insulating layer 122, the second upper gate insulating layer 123 and the upper interlayer insulating layer 160. The second source electrode 227 of each pixel area PA may be electrically connected to the first active source 221s1 and the second active source 221s2 of the second semiconductor pattern 221 in the corresponding pixel area PA passing through the first upper gate insulating layer 122, the second upper gate insulating layer 123 and the upper interlayer insulating layer 160.

The second upper gate insulating layer 123 and the upper interlayer insulating layer 160 may include first contact holes partially exposing the second sub-gate 223b of each pixel area PA. The upper interlayer insulating layer 160 may include second contact holes partially exposing the first sub-gate 223a of each pixel area PA. The connection gate 223c of each pixel area may be connected to the second sub-gate 223b of the corresponding pixel area PA through one of the first contact holes. The connection gate 223c of each pixel area may be connected to the first sub-gate 223a of the corresponding pixel area PA through one of the second contact holes. The first contact holes and the second contact holes may be formed simultaneously with a contact hole connecting the second drain electrode 225 of each pixel area PA to the first active drain 221d1 and the second active drain 221d2 of the corresponding pixel area PA and a contact hole connecting the second source electrode 227 of each pixel area PA to the first active source 221s1 and the second active source 221s2 of the corresponding pixel area PA. Thus, in the display apparatus according to the aspect of the present disclosure, decreasing efficiency in a process due to a process of forming the second gate electrode 223 of each pixel area PA may be minimized or reduced.

The first capacitor electrode 251 of each pixel area PA may be separated from the second capacitor electrode 252 of the corresponding pixel area PA by the second upper gate insulating layer 123. For example, the first capacitor electrode 251 of each pixel area PA may be disposed between the first upper gate insulating layer 122 and the second upper gate insulating layer 123. The second capacitor electrode 252 of each pixel area PA may be separated from the third capacitor electrode 253 of the corresponding pixel area PA by the upper interlayer insulating layer 160. For example, the second capacitor electrode of each pixel area PA may be disposed between the second upper gate insulating layer 123 and the upper interlayer insulating layer 160. The third capacitor electrode of each pixel area PA may be disposed on the upper interlayer insulating layer 160.

The circuit drain electrode 295 and the circuit source electrode 297 may be disposed on the upper interlayer insulating layer 160. For example, the circuit drain electrode 295 may be connected to the circuit drain region of the circuit semiconductor pattern 291 by passing through the lower gate insulating layer 121, the lower interlayer insulating layer 130, the separation insulating layer 140, the upper buffer layer 150, the first upper gate insulating layer 122, the second upper gate insulating layer 123 and the upper interlayer insulating layer 160. The circuit source electrode 297 may be connected to the circuit source region of the circuit semiconductor pattern 291 by passing through the lower gate insulating layer 121, the lower interlayer insulating layer 130, the separation insulating layer 140, the upper buffer layer 150, the first upper gate insulating layer 122, the second upper gate insulating layer 123 and the upper interlayer insulating layer 160. Thus, in the display apparatus according to the aspect of the present disclosure, decrease efficiency in a process due to a process of the forming the circuit thin film transistor 290 may be minimized or reduced.

The lower planarization layer 170 may be disposed on the upper interlayer insulating layer 160. The upper planarization layer 180 may be disposed on the lower planarization layer 170. The lower planarization layer 170 and the upper planarization layer 180 may remove a thickness difference due to the pixel driving circuit DC of each pixel area PA. For example, an upper surface of the upper planarization layer 180 opposite to the device substrate 100 may be a flat surface. The first drain electrode 215, the first source electrode 217, the second drain electrode 225, the second source electrode 227, the connection gate 223c and the third capacitor electrode 253 of each pixel area PA may be covered by the lower planarization layer 170. The lower planarization layer 170 and the upper planarization layer 180 may extend onto the bezel area BZ of the device substrate 100. For example, the lower planarization layer 170 and the upper planarization layer 180 may be stacked on the circuit drain electrode 295 and the circuit source electrode 297. A thickness difference due to the circuit thin film transistor 290 may be removed by the lower planarization layer 170 and the upper planarization layer 180.

The lower planarization layer 170 and the upper planarization layer 180 may include an insulating material. The lower planarization layer 170 and the upper planarization layer 180 may include a different material from the upper interlayer insulating layer 160. The lower planarization layer 170 and the upper planarization layer 180 may have a material having a relative high fluidity. For example, the lower planarization layer 170 and the upper planarization layer 180 may include an organic insulating material. The upper planarization layer 180 may include a same material as the lower planarization layer 170. For example, an interface between the lower planarization layer 170 and the upper planarization layer 180 may not be perceivable. For example, one or both of the lower planarization layer 170 and the upper planarization layer 180 may be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto.

The light-emitting device 500 of each pixel area PA may be disposed on the upper planarization layer 180 of the corresponding pixel area PA. For example, the light-emitting device 500 of each pixel area PA may be supported by the corresponding pixel area PA of the device substrate 100. The light-emitting device 500 of each pixel area PA may emit light of a specific color. For example, the light-emitting device 500 of each pixel area PA may include a first electrode 510, a light-emitting layer 520 and a second electrode 530, which are sequentially stacked on the upper planarization layer 180 of the corresponding pixel area PA.

The first electrode 510 may include a conductive material. The first electrode 510 may include a material having a high reflectance. For example, the first electrode 510 may include a metal such as aluminum (Al) or silver (Ag). The first electrode 510 may have a multi-layer structure. For example, the first electrode 510 may have a structure in which a reflective electrode made of a metal is disposed between transparent electrodes made of a transparent conductive material, such as ITO and IZO.

The light-emitting layer 520 may generate light with a luminance corresponding to a voltage difference between the first electrode 510 and the second electrode 530. For example, the light-emitting layer 520 may include at least one emission material layer (EML). The emission material layer may include an emission material. The emission material may include an organic material, an inorganic material, or a hybrid material. For example, the display apparatus according to the aspect of the present disclosure may be an organic light-emitting display apparatus including an organic emission material, but the present disclosure is not limited thereto.

The light-emitting layer 520 may include at least one functional layer to supply holes or electrons. For example, the light-emitting layer 520 may include at least one of a hole injection layer (HIL), a hole transport layer (HTL), an electron transport layer (ETL) and an electron injection layer (EIL). Thus, in the display apparatus according to the aspect of the present disclosure, efficiency of the light-emitting layer 520 may be improved.

The second electrode 530 may include a conductive material. The second electrode 530 may include a different material from the first electrode 510. A transmittance of the second electrode 530 may be greater than a transmittance of the first electrode 510. For example, the second electrode 530 may be a transparent electrode made of a transparent conductive material, such as ITO and IZO. Thus, in the display apparatus according to the aspect of the present disclosure, light generated by the light-emitting layer 520 may be emitted outside through the second electrode 530.

The light-emitting device 500 of each pixel area PA may be electrically connected to the second thin film transistor TR2 of the corresponding pixel area PA. For example, the first electrode 510 of each pixel area PA may be electrically connected to the second source electrode 227 of the corresponding pixel area PA. The first electrode 510 of each pixel area PA may include a portion in direct contact with the upper surface of the upper planarization layer 180 on the corresponding pixel area PA. The light-emitting layer 520 and the second electrode 530 of each pixel area PA may be stacked on a portion of the corresponding first electrode 510, which is in direct contact with the upper surface of the upper planarization layer 180. Thus, in the display apparatus according to the aspect of the present disclosure, deviation in the luminance according to the generating location of the light, which is emitted from the light-emitting device 500 of each pixel area PA may be prevented or reduced.

Intermediate electrodes 400 electrically connect the first electrode 510 of each pixel area PA to the second source electrode 227 of the corresponding pixel area PA and may be disposed between the lower planarization layer 170 and the upper planarization layer 180. The intermediate electrodes 400 may include a conductive material. For example, the intermediate electrodes 400 may include a metal, such as aluminum (Al), chrome (Cr), copper (Cu), molybdenum (Mo), titanium (Ti) and tungsten (W). Each of the intermediate electrodes 400 may be in direct contact with the second source electrode 227 and the first electrode 510 in one of the pixel areas PA. For example, the first electrode 510 of each pixel area PA may be in contact with one of the intermediate electrodes 400 by penetrating the upper planarization layer 180, and each of the intermediate electrodes 400 may be in contact with the second source electrode 227 in one of the pixel areas PA by penetrating the lower planarization layer 170. Thus, in the display apparatus according to the aspect of the present disclosure, the first electrode 510 of each pixel area PA may be stably connected to the second source electrode 227 of the corresponding pixel area PA. Therefore, in the display apparatus according to the aspect of the present disclosure, reliability of electrical connections between the pixel driving circuit DC and the light-emitting device 500 in each pixel area PA may be improved. However, the present disclosure is not limited thereto. For example, the intermediate electrodes 400 may be omitted and the first electrode 510 of each pixel area PA may be directly connected to the second source electrode 227 of the corresponding pixel area PA.

The bank insulating layer 190 may be disposed on the upper planarization layer 180. The bank insulating layer 190 may define an emission area in each pixel area PA. For example, the first electrode 510 of each pixel area PA may be partially exposed by the bank insulating layer 190. A portion of each first electrode 510 exposed by the bank insulating layer 190 may be in direct contact with the upper surface of the upper planarization layer 180. For example, the light-emitting layer 520 and the second electrode 530 of each pixel area PA may be stacked on a portion of the corresponding first electrode 510 exposed by the bank insulating layer 190. An edge of the first electrode 510 in each pixel area PA may be covered by the bank insulating layer 190. For example, the first electrode 510 of each pixel area PA may be insulated from the first electrode 510 of adjacent pixel area PA by the bank insulating layer 190. The bank insulating layer 190 may include an insulating material, such as acryl resin, epoxy resin, phenolic resin, polyamide resin, and/or polyimide resin, etc. Alternatively, the bank insulating layer 190 may include an inorganic insulating material such as silicon nitride, aluminum nitride, zirconium nitride, titanium nitride, hafnium nitride, tantalum nitride, silicon oxide, aluminum oxide, or titanium oxide, etc. For example, the bank insulating layer 190 may include an organic insulating material. The bank insulating layer 190 may include a different material from the upper planarization layer 180. In addition, the bank insulating layer 190 may be made of an insulating material containing a black material. The bank insulating layer 190 may be made of, for example, a transparent carbon-based mixture. Specifically, the bank insulating layer 190 may contain carbon black, but is not limited thereto. The bank insulating layer 190 may also be made of a transparent insulating material.

The light emitted from the light-emitting device 500 of each pixel area PA may display a different color from the light emitted from the light-emitting device 500 of adjacent pixel area PA. For example, the light-emitting layer 520 of each pixel area PA may be separated from the light-emitting layer 520 of adjacent pixel area PA. The light-emitting layer 520 of each pixel area PA may include an end on the bank insulating layer 190. For example, the light-emitting layer 520 of each pixel area PA may include a different material from the light-emitting layer 520 of adjacent pixel area PA.

A voltage applied to the second electrode 530 of each pixel area PA may be substantially equal a voltage applied to the second electrode 530 of adjacent pixel area PA. Substantially equal values are values that deviate based on normal process deviations and for all practical purposes are identical. For example, the second electrode 530 of each pixel area PA may be electrically connected to the second electrode 530 of adjacent pixel area PA. The second electrode 530 of each pixel area PA may include a same material as the second electrode 530 of adjacent pixel area PA. The second electrode 530 of each pixel area PA may be formed by a same process as the second electrode 530 of adjacent pixel area PA. For example, the second electrode 530 of each pixel area PA may be formed simultaneously with the second electrode 530 of adjacent pixel area PA. The second electrode 530 of each pixel area PA may be in direct contact with the second electrode 530 of adjacent pixel area PA. For example, the bank insulating layer 190 may be covered by the second electrode 530. Thus, in the display apparatus according to the aspect of the present disclosure, a process of forming the second electrode 530 in each pixel area PA may be simplified. And, in the display apparatus according to the aspect of the present disclosure, the luminance of the light generated by the light-emitting layer 520 in each pixel area PA may be adjusted by the data signal applied to the pixel driving circuit DC in the corresponding pixel area PA.

An encapsulation unit 600 may be disposed on the light-emitting device 500 of each pixel area PA. The encapsulation unit 600 may prevent or reduce damage of the light-emitting devices 500 due to external moisture and impact. The encapsulation unit 600 may have a multi-layer structure. For example, the encapsulation unit 600 may include a first encapsulating layer 610, a second encapsulating layer 620 and a third encapsulating layer 630, which are sequentially stacked, but the present disclosure is not limited thereto. The first encapsulating layer 610, the second encapsulating layer 620 and the third encapsulating layer 630 may include an insulating material. The second encapsulating layer 620 may include a different material from the first encapsulating layer 610 and the third encapsulating layer 630. For example, the first encapsulating layer 610 and the third encapsulating layer 630 may include an inorganic insulating material capable of low-temperature deposition, such as silicon oxide (SiOx) and silicon nitride (SiNx), and the second encapsulating layer 620 may include an organic insulating material. A thickness difference due to the light-emitting device 500 of each pixel area PA may be removed by the second encapsulating layer 620. For example, an upper surface of the encapsulation unit 600 opposite to the device substrate 100 may be a flat surface. Thus, in the display apparatus according to the aspect of the present disclosure, the damage of the light-emitting device 500 in each pixel area PA due to the external moisture and impact may be effectively prevented or reduced.

Accordingly, the display apparatus according to the aspect of the present disclosure may include the pixel driving circuits DC respectively connected to the light-emitting devices 500. The second thin film transistor TR2 of each pixel driving circuit DC may include the second gate electrode 223 on a portion of the second semiconductor pattern 221, and the second gate electrode 223 may include the first sub-gate 223a overlapping with the second channel region 221c of the second semiconductor pattern 221 and the second sub-gate 223b disposed between the second semiconductor pattern 221 and the first sub-gate 223a. The second channel region 221c may include the first active channel 221c1 completely overlapping with the second sub-gate 223b and the second active channel 221c2 partially overlapping with the second sub-gate 223b. Thus, in the display apparatus according to the aspect of the present disclosure, the driving current generated by the second thin film transistor TR2 in each pixel driving circuit DC to realize a low gray-scale image may be reduced without decreasing characteristics of the second thin film transistor TR2 in each pixel area PA. In addition, in the display apparatus according to the aspect of the present disclosure, the S-factor of the second thin film transistor TR2 in each pixel driving circuit DC may be increased. Therefore, in the display apparatus according to the aspect of the present disclosure, efficiency of the second thin film transistor TR2 of each pixel driving circuit DC may be improved. Further, in the display apparatus according to the aspect of the present disclosure, reliability of each pixel driving circuit DC and quality of the image may be improved.

The display apparatus according to the aspect of the present disclosure is described that the pixel driving circuit DC of each pixel area PA may consist of the first thin film transistor TR1, the second thin film transistor TR2 and the storage capacitor Cst. However, in the display apparatus according to another aspect of the present disclosure, the pixel driving circuit DC of each pixel area PA may include a driving thin film transistor and at least one switching thin film transistor. For example, in the display apparatus according to another aspect of the present disclosure, the pixel driving circuit DC of each pixel area PA may further include a third thin film transistor for initializing the storage capacitor Cst according to the gate signal. The third thin film transistor of each pixel area PA may include a third semiconductor pattern, a third gate electrode, a third drain electrode and a third source electrode. For example, the third gate electrode of each pixel area PA may be electrically connected to the corresponding gate line GL, the third drain electrode of each pixel area PA may be electrically connected to an initial line applying an initial signal, and the third source electrode of each pixel area PA may be electrically connected to the storage capacitor Cst of the corresponding pixel area PA. Thus, in the display apparatus according to another aspect of the present disclosure, the degree of freedom in configuration of each pixel driving circuit DC may be improved.

In the display apparatus according to the aspect of the present disclosure, the location and the electrical connection of the first drain electrode 215, the first source electrode 217, the second drain electrodes 225 and the second source electrode 227 in each pixel driving circuit DC may vary depending on the configuration of the corresponding pixel driving circuit DC and/or the type of the corresponding thin film transistors TR1 and TR2. For example, in the display apparatus according to another aspect of the present disclosure, the second gate electrode 223 of each pixel driving circuit DC may be electrically connected to the first drain electrode 215 of the corresponding pixel driving circuit DC. Thus, in the display apparatus according to another aspect of the present disclosure, the degree of freedom in the configuration of each pixel driving circuit DC and the type of each thin film transistor TR1 and TR2 may be improved.

The display apparatus according to the aspect of the present disclosure is described that the first semiconductor pattern 211 and the second semiconductor pattern 221 of each pixel area PA may be made of an oxide semiconductor. However, in the display apparatus according to another aspect of the present disclosure, the second semiconductor pattern 221 of each pixel area PA may include a different material from the first semiconductor pattern 211 of the corresponding pixel area PA. For example, in the display apparatus according to another aspect of the present disclosure, the first semiconductor pattern 211 of each pixel area PA may include amorphous silicon (a-Si) or polycrystalline silicon (poly-Si). The first thin film transistor TR1 of each pixel area PA may be formed to have a same structure as the circuit thin film transistor 290. For example, the first semiconductor pattern 211 of each pixel area PA may be disposed between the lower buffer layer 110 and the lower gate insulating layer 121, and the first gate electrode 213 of each pixel area PA may be disposed between the lower gate insulating layer 121 and the lower interlayer insulating layer 130. The first semiconductor pattern 211 of each pixel area PA may include a same material as the circuit semiconductor pattern 291. For example, the first semiconductor pattern of each pixel area PA may include low-temperature poly-Si (LTPS). In the display apparatus according to another aspect of the present disclosure, the first light-blocking pattern 310 of each pixel area PA may not be formed. Thus, in the display apparatus according to another aspect of the present disclosure, the degree of freedom in the configuration of each pixel driving circuit DC and the type of each thin film transistor TR1 and TR2 may be improved.

The display apparatus according to the aspect of the present disclosure is described that the first active region A1 of each pixel area PA may be disposed between the second active region A2 of the corresponding pixel area PA and the connection gate 223c. However, in the display apparatus according to another aspect of the present disclosure, the second active region A2 of each pixel area PA may be disposed between the first active region A1 of the corresponding pixel area PA and the connection gate 223c, as shown in FIG. 10. Thus, in the display apparatus according to another aspect of the present disclosure, the degree of freedom in the location of the first active region A1 and the second active region A2 in each pixel area PA may be improved.

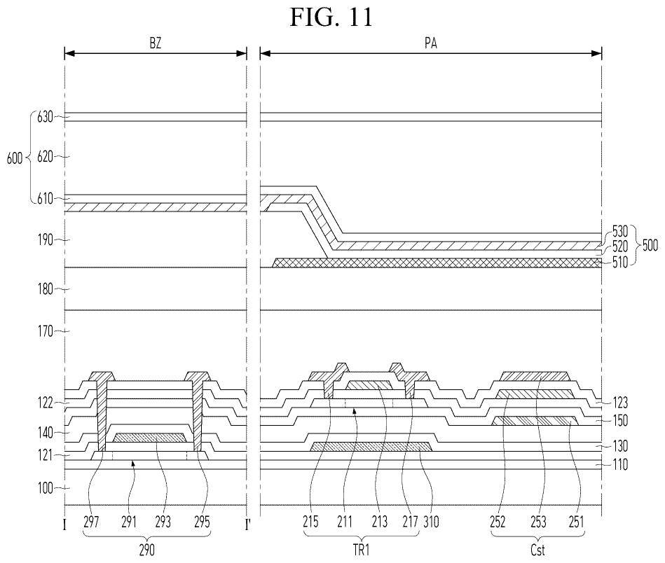

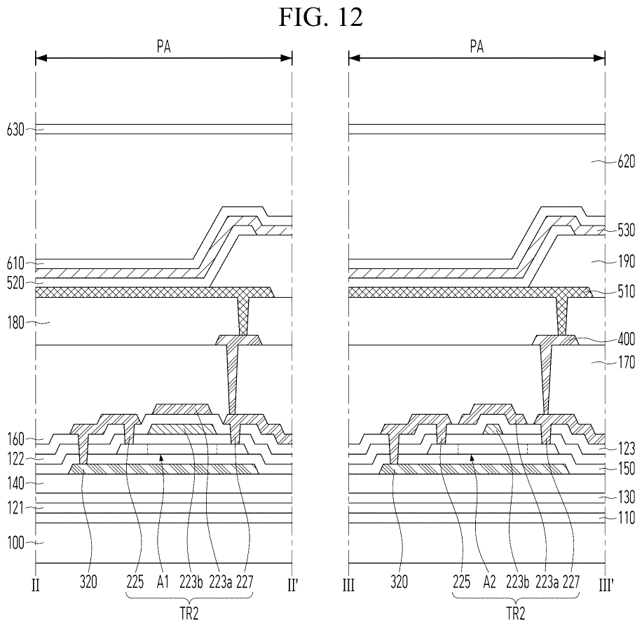

The display apparatus according to the aspect of the present disclosure is described that the first sub-gate 223a of each pixel area PA may be disposed on a different layer from the first drain electrode 215, the first source electrode 217, the second drain electrode 225 and the second source electrode 227 of the corresponding pixel area PA. However, in the display apparatus according to another aspect of the present disclosure, the first sub-gate 223a of each pixel area PA may be disposed on a same layer as the second drain electrode 225 and the second source electrode 227 of the corresponding pixel area PA, as shown in FIGS. 11 and 12. The first sub-gate 223a of each pixel area PA may include a same material as the second drain electrode 225 and the second source electrode 227 of the corresponding pixel area PA. The first sub-gate 223a of each pixel area PA may be formed by a same process as the second drain electrode 225 and the second source electrode 227 of the corresponding pixel area PA. For example, the first sub-gate 223a of each pixel area PA may be formed simultaneously with the second drain electrode 225 and the second source electrode 227 of the corresponding pixel area PA. The first sub-gate 223a of each pixel area PA may be separated from the second drain electrode 225 and the second source electrode 227 of the corresponding pixel area PA. For example, the first sub-gate 223a of each pixel area PA may be in direct contact with the second sub-gate 223b of the corresponding pixel area PA by penetrating the second upper gate insulating layer 123. Thus, in the display apparatus according to another aspect of the present disclosure, a decrease in process efficiency due to a process of forming the second gate electrode 223 in each pixel area PA may be minimized or reduced, and efficiency of the second thin film transistor TR2 in each pixel area PA may be improved.

In the display apparatus according to another aspect of the present disclosure, the first capacitor electrode 251 of each pixel area PA may be disposed on a same layer as the second light-blocking pattern 320 of the corresponding pixel area PA, the second capacitor electrode 252 of each pixel area PA may be disposed on a same layer as the second sub-gate 223b of the corresponding pixel area PA, and the third capacitor electrode of each pixel area PA may be disposed on a same layer as the first sub-gate 223a of the corresponding pixel area PA. For example, in the display apparatus according to another aspect of the present disclosure, the storage capacitor Cst of each pixel area PA may include the first capacitor electrode 251 between the separation insulating layer 140 and the upper buffer layer 150, the second capacitor electrode 252 between the first upper gate insulating layer 122 and the second upper gate insulating layer 123, and the third capacitor electrode 253 between the second upper gate insulating layer 123 and the lower planarization layer 170. Thus, in the display apparatus according to another aspect of the present disclosure, increase in a size of the storage capacitor in each pixel area PA according to the location of the first sub-gate 223a in the corresponding pixel area PA may be minimized or reduced. Therefore, in the display apparatus according to another aspect of the present disclosure, the degree of freedom in the configuration of the pixel driving circuit DC in each pixel area PA may be improved.

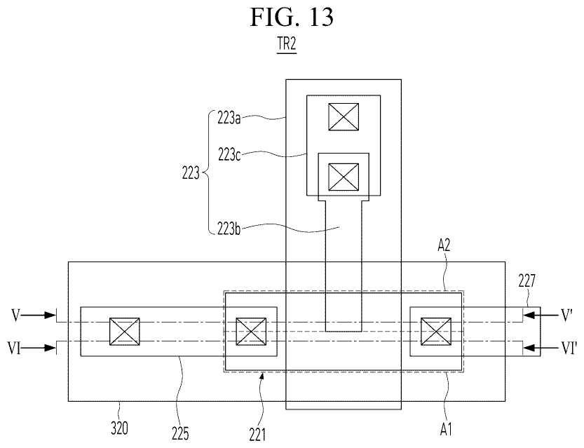

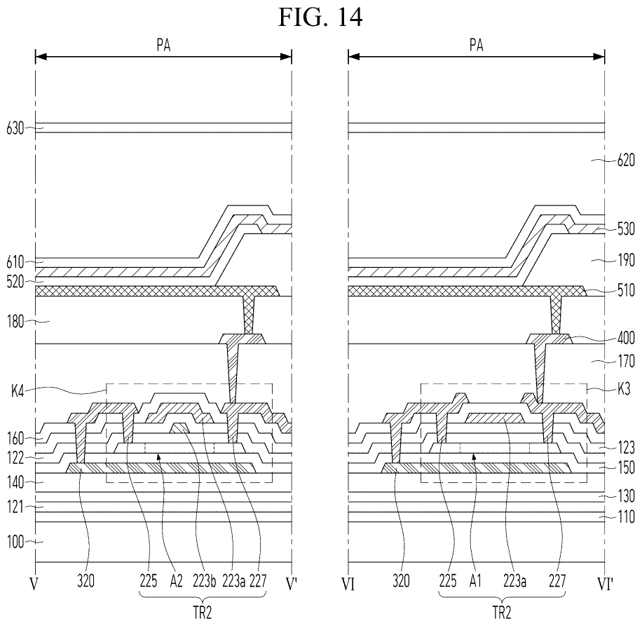

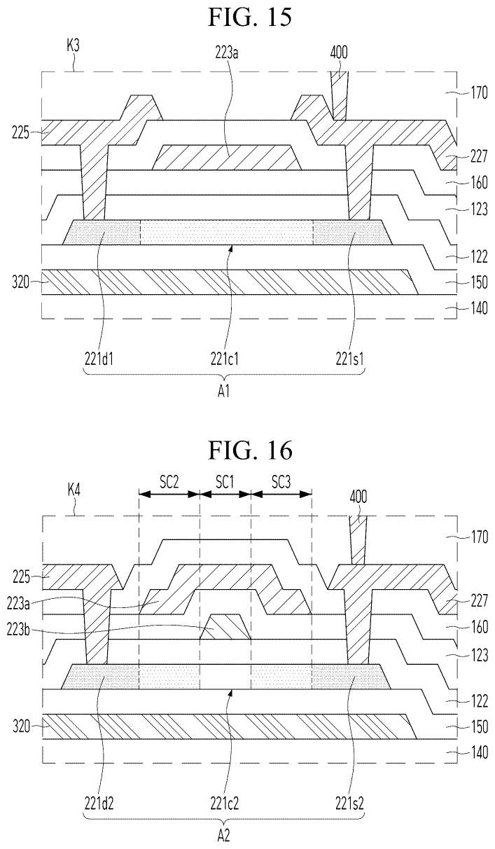

The display apparatus according to the aspect of the present disclosure is described that a channel of the first active region A1 in each pixel area PA may be formed by the second sub-gate 223b of the corresponding pixel area PA. However, in the display apparatus according to another aspect of the present disclosure, the first active region A1 in each pixel area PA may be activated by the first sub-gate 223a of the corresponding pixel area PA. For example, in the display apparatus according to another aspect of the present disclosure, the first active region A1 in each pixel area PA may be disposed outside the second sub-gate 223b of the corresponding pixel area PA, as shown in FIGS. 13 to 16.

Only the first upper gate insulating layer 122 and the second upper gate insulating layer 123 may be disposed between the first active channel 221c1 of the first active channel 221c1 and the first sub-gate 223a in each pixel area PA. The second active channel 221c2 of each pixel area PA may include the first sub-channel SC1, the second sub-channel SC2 and the third sub-channel SC3. The first sub-channel SC1 of each pixel area PA may overlap the second sub-gate 223b of the corresponding pixel area PA. The second sub-channel SC2 and the third sub-channel SC3 of each pixel area PA may be disposed outside the second sub-gate 223b of the corresponding pixel area PA. For example, only the first upper gate insulating layer 122 and the second upper gate insulating layer 123 may be disposed between the second sub-channel SC2 and the first sub-gate 223a in each pixel area PA and between the third sub-channel SC3 and the first sub-gate 223a in each pixel area PA. Thus, in the display apparatus according to another aspect of the present disclosure, a channel of the first active channel 221c1, a channel of the second sub-channel SC2 and a channel of the third sub-channel SC3 may be formed by a voltage applied to the first sub-gate 223a, and a channel of the first sub-channel SC1 may be formed by a voltage applied to the second sub-gate 223b.

A channel of the first active channel 221c1, a channel of the second sub-channel SC2 and a channel of the third sub-channel SC3 in each pixel area PA may be formed at a voltage lower than a channel of the first sub-channel SC1 in the corresponding pixel area PA. For example, the first active channel 221c1, the second sub-channel SC2 and the third sub-channel SC3 of each pixel area PA may be doped with conductive impurities. The first active channel 221c1, the second sub-channel SC2 and the third sub-channel SC3 of each pixel area PA may have a smaller resistance than the first sub-channel SC1 of the corresponding pixel area PA. A resistance of the first active channel 221c1, a resistance of the second sub-channel SC2 and a resistance of the third sub-channel SC3 in each pixel area PA may be larger than a resistance of the first active drain 221d1, a resistance of the second active drain 221d2, a resistance of the first active source 221s1 and a resistance of the second active source 221s2 in the corresponding pixel area PA. For example, the first active drain 221d1, the second active drain 221d2, the first active source 221s1 and the second active source 221s2 of each pixel area PA may be doped with conductive impurities having a higher concentration than the first active channel 221c1, the second sub-channel SC2 and the third sub-channel SC3 of the corresponding pixel area PA. The second sub-channel SC2 disposed between the second active drain 221d2 and the first sub-channel SC1 in each pixel area PA and the third sub-channel SC3 disposed between the first sub-channel SC1 and the second active source 221s2 in each pixel area PA may function as a lightly doped drain (LDD) region of the second active region A2 in the corresponding pixel area PA. Thus, in the display apparatus according to another aspect of the present disclosure, a channel of the first sub-channel SC1 in each pixel area PA may function as an effective channel of the second active channel 221c2 in the corresponding pixel area PA.

In the display apparatus according to another aspect of the present disclosure, only the first active region A1 of each pixel area PA may be activated, when a relative low voltage is applied to the first sub-gate 223a and the second sub-gate 223b of each pixel area PA. Thus, in the display apparatus according to another aspect of the present disclosure, occurrence of stains may be prevented or reduced and quality of a low gray-scale image may be improved, without deterioration in the characteristics of the second thin film transistor TR2 in each pixel area PA.

A distance between the first active channel 221c1 and the first sub-gate 223a in each pixel area PA may be greater than a distance between the first sub-channel SC1 and the second sub-gate 223b in the corresponding pixel area PA. Thus, in the display apparatus according to another aspect of the present disclosure, the first active region A1 of the second thin film transistor TR2 in each pixel may have a relative large S-factor. That is, in the display apparatus according to another aspect of the present disclosure, deviation in the driving current generated by the second thin film transistor TR2 of each pixel area PA may be effectively reduced. Therefore, in the display apparatus according to another aspect of the present disclosure, efficiency of the second thin film transistor TR2 in each pixel area PA and quality of the image may be improved.

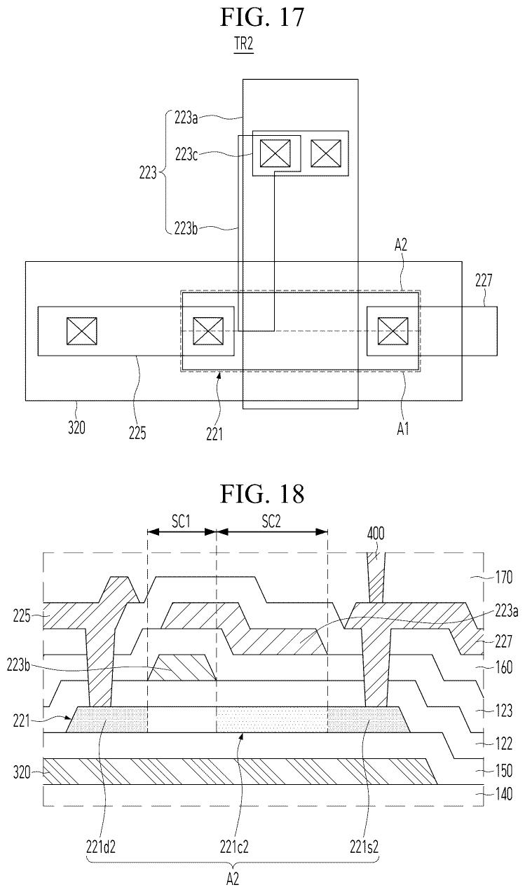

The display apparatus according to the aspect of the present disclosure is described that the second active region A2 of each pixel area PA may include the first sub-channel SC1 disposed between the second sub-channel SC2 and the third sub-channel SC3 of the corresponding pixel area PA. However, in the display apparatus according to another aspect of the present disclosure, the second active region A2 of each pixel area PA may have various structures. For example, in the display apparatus according to another aspect of the present disclosure, the second semiconductor pattern 221 may include the first active region A1 disposed outside the second sub-gate 223b and the second active region A2 disposed parallel to the first active region A1, wherein the second active region A2 may be composed of the first sub-channel SC1 overlapping with the second sub-gate 223b and the second sub-channel SC2 disposed outside the second sub-gate 223b, as shown in FIGS. 17 and 18.

The first sub-channel SC1 may be disposed between the second active drain 221d2 and the second sub-channel SC2. The second sub-channel SC2 may be disposed between the first sub-channel SC1 and the second active source 221s2. The amount of oxygen contained in the first sub-channel SC1 may be different from the amount of oxygen contained in the second sub-channel SC2. For example, the second sub-channel SC2 may have a resistance between the second active source 221s2 and the first sub-channel SC1. A channel of the second sub-channel SC2 may be formed at a lower voltage than a channel of the first sub-channel SC1. Thus, in the display apparatus according to another aspect of the present disclosure, the first sub-channel SC1 may function as an effective channel of the second active area A2. Therefore, in the display apparatus according to another aspect of the present disclosure, the degree of freedom in configuration of the second active region A2 in each pixel area PA may be improved.

In the display apparatus according to another aspect of the present disclosure, a length of the second sub-channel SC2 may be different from a length of the first sub-channel SC1. For example, in the display apparatus according to the another aspect of the present disclosure, a length of the first sub-channel SC1 may be smaller than a length of the second sub-channel SC2, as shown in FIGS. 17 and 18. Thus, in the display apparatus according to another aspect of the present disclosure, an effective channel region of the second active region A2 may be adjusted by a length of the first sub-channel SC1. Therefore, in the display apparatus according to another aspect of the present disclosure, the driving current generated by the second thin film transistor TR2 of each pixel area PA may be effectively adjusted, when both of the first active region A1 and the second active region A2 of the corresponding pixel area PA are activated.

The display apparatus according to the aspect of the present disclosure is described that the second active region A2 of each pixel area PA may have a same size as the first active region A1 of the corresponding pixel area PA. However, in the display apparatus according to another aspect of the present disclosure, the second active region A2 of each pixel area PA may have a different width and/or length from the first active region A1 of the corresponding pixel area PA. Thus, in the display apparatus according to another aspect of the present disclosure, when only the first active region A1 of each pixel area PA is activated, the driving current generated by the second thin film transistor TR2 of each pixel area PA may be effectively adjusted, without deterioration in the characteristics of the second thin film transistor TR2 in the corresponding pixel area PA.

The display apparatus according to the aspect of the present disclosure is described that the second active region A2 of each pixel area PA may be formed simultaneously with the first active region A1 of the corresponding pixel area PA. However, in the display apparatus according to another aspect of the present disclosure, the second active region A2 of each pixel area PA may include a different material from the first active region A1 of the corresponding pixel area PA. Thus, in the display apparatus according to another aspect of the present disclosure, when only the first active region A1 of each pixel area PA is activated, the driving current of the second thin film transistor TR2 of each pixel area PA may be effectively adjusted. Therefore, in the display apparatus according to another aspect of the present disclosure, efficiency of the second thin film transistor TR2 in each pixel area PA may be improved.

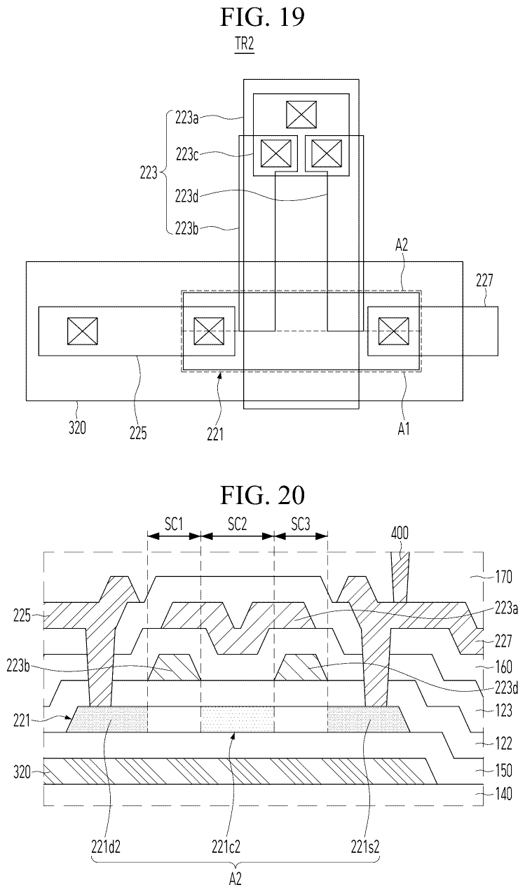

In the display apparatus according to another aspect of the present disclosure, the first sub-channel SC1 and the third sub-channel SC3 of the second active region A2 may be activated before the second sub-channel SC2 of the second active region A2. For example, in the display apparatus according to another aspect of the present disclosure, the second active region A2 may include the second sub-channel SC2 disposed between the first sub-channel SC1 and the third sub-channel SC3, a resistance of the second sub-channel SC2 may be smaller than a resistance of the first sub-channel SC1 and a resistance of the third sub-channel SC3, as shown in FIGS. 19 and 20. The second gate electrode 223 may include a second sub-gate 223b overlapping with the first sub-channel SC1 and a third sub-gate 223d overlapping with the third sub-channel SC3. The second sub-gate 223b and the third sub-gate 223d may be electrically connected to the first sub-gate 223a by the connection gate 223c. The second sub-channel SC2 may be disposed outside the second sub-gate 223b and the third sub-gate 223d. The second sub-channel SC2 may overlap the first sub-gate 223a. Thus, in the display apparatus according to another aspect of the present disclosure, a channel of the first sub-channel SC1 and a channel of the third sub-channel SC3 may function as an effective channel of the second active region A2. Therefore, in the display apparatus according to another aspect of the present disclosure, an effective channel of the second active region A2 may be effectively adjusted.

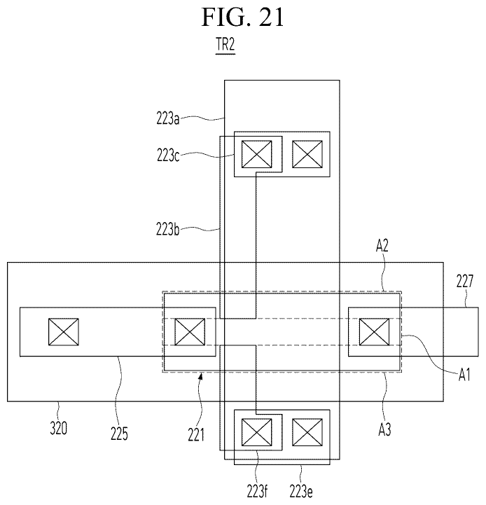

The display apparatus according to the aspect of the present disclosure is described that the second semiconductor pattern 221 of each pixel area PA may include the first active region A1 and the second active region A2, wherein the second active region A2 may be activated at a lower voltage than the first active region A1. However, in the display apparatus according to another aspect of the present disclosure, the second semiconductor pattern 221 of each pixel area PA may include a plurality of active regions A1 and A2. For example, in the display apparatus according to another aspect of the present disclosure, the second semiconductor pattern 221 may include a first active region A1 disposed between a second active region A2 and a third active region A3, as shown in FIG. 21. Each of the first active region A1, the second active region A2 and the third active region A3 may include an active channel disposed between an active drain and an active source. The second drain electrode 225 may be electrically connected to an active drain of the first active region A1, an active drain of the second active region A2 and an active drain of the third active region A3. The second source electrode 227 may be electrically connected to an active source of the first active region A1, an active source of the second active region A2 and an active source of the third active region A3.

The second gate electrode on the second semiconductor pattern 221 may include a first sub-gate 223a, a second sub-gate 223b, a first connection gate 223c, a third sub-gate 223f and a second connection gate 223e. The first active region A1 may be activated before the second active region A2 and the third active region A3. For example, the second sub-gate 223b electrically connected to the first sub-gate 223a by the first connection gate 223c may partially overlap an active channel of the second active region A2, the third sub-gate 223f electrically connected to the first sub-gate 223a by the second connection gate 223e may partially overlap an active channel of the third active region A3, and an active channel of the first active region A1 may be disposed outside the second sub-gate 223b and the third sub-gate 223f. An active channel of the first active region A1 may have an electrical conductivity corresponding to a voltage applied to the first sub-gate 223a. Thus, in the display apparatus according to another aspect of the present disclosure, if a low voltage is applied to the second gate electrode, only the first active region A1 may be activated. And, in the display apparatus according to another aspect of the present disclosure, if a high voltage is applied to the second gate electrode, all of the first active region A1, the second active region A2 and the third active region A3 may be activated. Therefore, in the display apparatus according to another aspect of the present disclosure, the driving current generated by the second thin film transistor TR2 of each pixel area PA may be effectively adjusted according to the gray-scale of the realized image. Also, in the display apparatus according to another aspect of the present disclosure, power consumption required to realize a low gray-scale image may be reduced, without deterioration in the characteristics of the second thin film transistor TR2 in each pixel area PA.

In the display apparatus according to another aspect of the present disclosure, a channel of an active channel of the third active region A3 may be formed at a different voltage from a channel of an active channel of the second active region A2. For example, in the display apparatus according to another aspect of the present disclosure, a channel of an active channel of the first active region A1 may be formed at a first threshold voltage, a channel of an active channel of the second active region A2 may be formed at a second threshold voltage higher than the first threshold voltage, and a channel of an active channel of the third active region A3 may be formed at a third threshold voltage higher than the second threshold voltage. Thus, in the display apparatus according to another aspect of the present disclosure, a width of an activating region of the second semiconductor pattern 221 in each pixel area PA may be controlled according to the gray-scale of the image. Therefore, in the display apparatus according to another aspect of the present disclosure, efficiency of the second thin film transistor TR2 in each pixel area may be effectively improved. That is, in the display apparatus according to another aspect of the present disclosure, efficiency of the pixel driving circuit in each pixel area may be improved, without deterioration in the characteristics of the second thin film transistor TR2 in the corresponding pixel area. And, in the display apparatus according to another aspect of the present disclosure, power consumption may be effectively reduced.

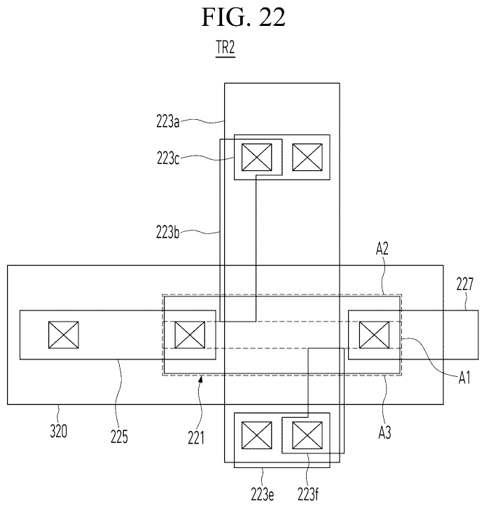

In the display apparatus according to another aspect of the present disclosure, the second sub-gate 223b and the third sub-gate 223f may be placed in various locations. For example, in the display apparatus according to another aspect of the present disclosure, the second sub-gate 223b may be disposed close to the second drain electrode 225, and the third sub-gate 223f may be disposed close to the second source electrode 227, as shown in FIG. 22. Thus, in the display apparatus according to another aspect of the present disclosure, the degree of freedom in configuration of the second gate electrode in each pixel area may be improved.

In the result, the display apparatus according to the embodiments of the present disclosure may comprise the pixel driving circuit electrically connected to the light-emitting device, wherein a driving thin film transistor of the pixel driving circuit may include a semiconductor pattern, a first sub-gate and a second sub-gate, wherein the second sub-gate may be disposed between the semiconductor pattern and the first sub-gate, and wherein at least a portion of a channel region of the semiconductor pattern may not overlap the second sub-gate. Thus, in the display apparatus according to the embodiments of the present disclosure, only a portion of the semiconductor pattern may be activated, when a low gray-scale image is realized. That is, in the display apparatus according to the embodiments of the present disclosure, when a low gray-scale image is realized, occurrence of stains may be prevented or reduced, without deterioration in the characteristics of the driving thin film transistor. Thereby, in the display apparatus according to the embodiments of the present disclosure, quality of the image provided to the user may be improved. And, in the display apparatus according to the embodiments of the present disclosure, lower power driving may be possible, and power consumption may be reduced.

What is claimed is:

1. A display apparatus comprising:
a semiconductor pattern including a first active region and a second active region disposed parallel to the first active region;
a first sub-gate on the semiconductor pattern, the first sub-gate overlapping a first active channel of the first active region and a second active channel of the second active region;
a second sub-gate between the semiconductor pattern and the first sub-gate, wherein the second sub-gate is insulated from the semiconductor pattern;
a drain electrode electrically connected to a drain region of the semiconductor pattern; and
a source electrode electrically connected to a source region of the semiconductor pattern,
wherein a width of the second sub-gate on the second active channel is smaller than a width of the second sub-gate on the first active channel.

2. The display apparatus according to claim 1, wherein the width of the second sub-gate on the first active channel is greater than a width of the first sub-gate on the first active channel.

3. The display apparatus according to claim 1, wherein the second sub-gate is electrically connected to the first sub-gate, and
wherein the first sub-gate is disposed on a different layer from the second sub-gate.

4. The display apparatus according to claim 3, wherein the first sub-gate is disposed on a different layer from the drain electrode and the source electrode.

5. The display apparatus according to claim 4, wherein the second sub-gate is electrically connected to the first sub-gate through a connection gate disposed outside the semiconductor pattern.

6. The display apparatus according to claim 3, wherein the first sub-gate is disposed on a same layer as the drain electrode and the source electrode and spaced apart from the drain electrode and the source electrode.

7. The display apparatus according to claim 3, wherein the second active channel includes a first sub-channel overlapping with the second sub-gate and a second sub-channel disposed outside the second sub-gate, and
wherein a distance between the first sub-channel and the second sub-gate is smaller than a distance between the second sub-channel and the first sub-gate.

8. The display apparatus according to claim 7, wherein a resistance of the second sub-channel is substantially equal to a resistance of the first sub-channel.

9. The display apparatus according to claim 7, wherein the second active channel includes a third sub-channel disposed outside the second sub-gate,
wherein a distance between the third sub-channel and the first sub-gate is greater than a distance between the first sub-channel and the second sub-gate, and
wherein the first sub-channel is disposed between the second sub-channel and the third sub-channel.

10. The display apparatus according to claim 1, wherein the semiconductor pattern comprises an oxide semiconductor, and
wherein an amount of oxygen in the second active channel is substantially equal to an amount of oxygen in the first active channel.

11. The display apparatus according to claim 1, wherein a width of the second sub-gate on the second active channel is smaller than a width of the first sub-gate on the second active channel.

12. The display apparatus of claim 1, wherein the semiconductor pattern including the first active region and the second active region comprises a single doped region, and the first active region and the second active region are doped with different impurities.

13. A display apparatus comprising:
a first thin film transistor on a pixel area of a device substrate, the first thin film transistor including a first semiconductor pattern and a first gate electrode;
a second thin film transistor on the pixel area of the device substrate, the second thin film transistor including a second semiconductor pattern and a second gate electrode; and
a light-emitting device on the pixel area of the device substrate, the light-emitting device electrically connected to the second thin film transistor,
wherein the second gate electrode includes a first sub-gate overlapping with a channel region of the second semiconductor pattern and a second sub-gate disposed between the second semiconductor pattern and the first sub-gate,
wherein the channel region of the second semiconductor pattern includes a first active channel including a portion overlapping with the second sub-gate and a second active channel disposed outside the second sub-gate, and
wherein the first active channel having a larger resistance than the second active channel includes a first sub-channel overlapping with the second sub-gate and a second sub-channel disposed outside the second sub-gate.

14. The display apparatus according to claim 13, wherein a resistance of the second sub-channel is a same as a resistance of the second active channel.

15. The display apparatus according to claim 13, wherein the second sub-gate includes a different material from the first sub-gate.

16. The display apparatus according to claim 15, wherein the first gate electrode includes a same material as the second sub-gate.

17. The display apparatus according to claim 15, further comprising:
a first gate insulating layer between the second semiconductor pattern and the second sub-gate; and
a second gate insulating layer between the second sub-gate and the first sub-gate,
wherein the first gate electrode is disposed between the first gate insulating layer and the second gate insulating layer.

18. The display apparatus according to claim 17, further comprising:
an upper interlayer insulating layer on the second gate insulating layer, the upper interlayer insulating layer covering the first sub-gate; and
a storage capacitor on the pixel area of the device substrate,
wherein the storage capacitor includes a first capacitor electrode disposed between the first gate insulating layer and the second gate insulating layer, a second capacitor electrode disposed between the second gate insulating layer and the upper interlayer insulating layer, and a third capacitor electrode disposed on the upper interlayer insulating layer.

19. The display apparatus according to claim 13, wherein a channel region of the first semiconductor pattern has a larger resistance than a drain region and a source region of the first semiconductor pattern, and
wherein the first sub-channel has a same resistance as the channel region of the first semiconductor pattern.

20. The display apparatus according to claim 13, wherein the second gate electrode further includes a third sub-gate disposed on a same layer as the second sub-gate,
wherein the channel region of the second semiconductor pattern further includes a third active channel including a portion overlapping with the third sub-gate, and
wherein the second active channel is disposed between the first active channel and the third active channel.
